(19) United States
(12) Patent Application Publication
(10) Pub. No.: US 2026/0179662 A1
(43) Pub. Date: Jun. 25, 2026

(54) SEMICONDUCTOR MEMORY DEVICE AND MANUFACTURING METHOD THEREFOR

(71) Applicant: Kioxia Corporation, Tokyo (JP)

(72) Inventors: Yoshiro SHIMOJO, Nagoya Aichi (JP); Kouji MATSUO, Ama Aichi (JP); Shunichi SENO, Yokkaichi Mie (JP); Renya SAKAKI, Yokkaichi Mie (JP)

(21) Appl. No.: 19/321,324

(22) Filed: Sep. 8, 2025

(30) Foreign Application Priority Data
Dec. 25, 2024 (JP) 2024-229452

(51) Int. Cl. G11C 5/06; H01L 23/00; H01L 25/18; H10B 43/10; H10B 43/27; H10B 43/40; H10D 80/30

(52) U.S. Cl. CPC G11C 5/063; H10B 43/10; H10B 43/27; H10B 43/40; H10D 80/30; H10W 90/00; H10W 90/792

(57) ABSTRACT

A semiconductor memory device includes first electrode films and first and second insulating films arranged in a first direction, a first region in which the first electrode films and the first insulating films are alternately stacked, a second region adjacent to the first region in a second direction and in which the first and second insulating films are alternately stacked, a third region extending from the first stacked region and in which the first electrode and insulating films are alternately stacked, a semiconductor layer that penetrates the first electrode films and the first insulating films in the first stacked region and forms memory cells at intersections with the first electrode films, contacts extending in the second stacked region, each contact reaching, in the first direction, a level of a corresponding one of the first electrode films, and connection layers electrically connecting the contacts and the corresponding electrode films.

### CROSS-REFERENCE TO RELATED APPLICATION

This application is based upon and claims the benefit of priority from Japanese Patent Application No. 2024-229452, filed Dec. 25, 2024, the entire contents of which are incorporated herein by reference.

### FIELD

Embodiments described herein relate generally to a semiconductor memory device and a manufacturing method therefor.

### BACKGROUND

A semiconductor memory device such as a NAND flash memory has a memory cell array in which a plurality of memory cells are disposed three-dimensionally. Such a memory cell array includes a plurality of electrode films functioning as word lines and a plurality of insulating films. These electrode films and insulating films are alternately stacked. Each electrode film is formed by replacing a sacrificial film from a stacked body of a plurality of sacrificial films and a plurality of insulating films with a conductive material. When the sacrificial film is removed in such a replacement process, the stacked body can bend under its own weight.

### BRIEF DESCRIPTION OF THE DRAWINGS

FIG. 1 is a cross-sectional view of a semiconductor memory device according to a first embodiment.

FIG. 2 is an enlarged cross-sectional view of a memory cell array according to the first embodiment.

FIG. 3 is a cross-sectional view of a manufacturing process, from bonding of an array wafer and a circuit wafer through completion of the semiconductor memory device.

FIG. 4 is a cross-sectional view of the manufacturing process, continuing from FIG. 3.

FIG. 5 is a cross-sectional view of the manufacturing process, continuing from FIG. 4.

FIG. 6 is a cross-sectional view of the manufacturing process, continuing from FIG. 5.

FIG. 7 is a plan view of the memory cell array according to the first embodiment.

FIG. 8 is a cross-sectional view of the memory cell array according to the first embodiment.

FIG. 9 is a plan view of a manufacturing method for the semiconductor memory device according to the first embodiment.

FIG. 10 is a cross-sectional view of the manufacturing method for the semiconductor memory device according to the first embodiment.

FIG. 11 is a cross-sectional view of the manufacturing method, continuing from FIG. 10.

FIG. 12 is a cross-sectional view of the manufacturing method, continuing from FIG. 11.

FIG. 13 is a plan view of the manufacturing method, continuing from FIG. 12.

FIG. 14 is a cross-sectional view of the manufacturing method, continuing from FIG. 12.

FIG. 15 is a cross-sectional view of the manufacturing method, continuing from FIG. 14.

FIG. 16 is a cross-sectional view of the manufacturing method, continuing from FIG. 15.

FIG. 17 is a cross-sectional view of the manufacturing method, continuing from FIG. 16.

FIG. 18 is a plan view of the manufacturing method, continuing from FIG. 17.

FIG. 19 is a cross-sectional view of the manufacturing method, continuing from FIG. 17.

FIG. 20 is a plan view of the manufacturing method, continuing from FIG. 18.

FIG. 21 is a cross-sectional view of the manufacturing method, continuing from FIG. 19.

FIG. 22 is a cross-sectional view of the manufacturing method, continuing from FIG. 21.

FIG. 23 is a plan view of the manufacturing method, continuing from FIG. 22.

FIG. 24 is a cross-sectional view of the manufacturing method, continuing from FIG. 22.

FIG. 25 is a plan view of the manufacturing method, continuing from FIG. 23.

FIG. 26 is a cross-sectional view of the manufacturing method, continuing from FIG. 24.

FIG. 27 is a plan view of the manufacturing method, continuing from FIG. 25.

FIG. 28 is a cross-sectional view of the manufacturing method, continuing from FIG. 26.

FIG. 29 is a cross-sectional view of the manufacturing method, continuing from FIG. 28.

FIG. 30 is a cross-sectional view of the manufacturing method, continuing from FIG. 29.

FIG. 31 is a cross-sectional view of the manufacturing method, continuing from FIG. 30.

FIG. 32 is a plan view of a memory cell array according to a second embodiment.

FIG. 33 is a plan view of a manufacturing method for a semiconductor memory device according to the second embodiment.

FIG. 34 is a plan view of the manufacturing method, continuing from FIG. 33.

FIG. 35 is a plan view of the manufacturing method, continuing from FIG. 34.

FIG. 36 is a plan view of the manufacturing method, continuing from FIG. 35.

FIG. 37 is a plan view of the manufacturing method, continuing from FIG. 36.

FIG. 38 is a plan view of the manufacturing method, continuing from FIG. 37.

FIG. 39 is a plan view of the manufacturing method, continuing from FIG. 38.

FIG. 40 is a plan view of a semiconductor memory device according to a third embodiment.

FIG. 41 is a cross-sectional view taken along line A-A of FIG. 40.

FIG. 42 is a cross-sectional view taken along line B-B of FIG. 40.

FIG. 43 is a plan view of a semiconductor memory device according to a fourth embodiment.

FIG. 44 is a plan view of the semiconductor memory device according to the fourth embodiment.

FIG. 45 is a cross-sectional view taken along line A-A of FIG. 44.

FIG. 46 is a cross-sectional view taken along line B-B of FIG. 44.

### DETAILED DESCRIPTION

Embodiments provide a semiconductor memory device and a manufacturing method therefor which are capable of curb depression of a stacked body when a sacrificial film is replaced with a conductive material from a stacked body of a plurality of sacrificial films and a plurality of insulating films.

In general, according to one embodiment, a semiconductor memory device comprises: a plurality of first electrode films arranged in a first direction; a plurality of first insulating films arranged in the first direction; a plurality of second insulating films arranged in the first direction; a first stacked region in which the first electrode films and the first insulating films are alternately stacked in the first direction; a second stacked region disposed adjacent to the first stacked region in a second direction that is perpendicular to the first direction and in which the first insulating films and the second insulating films are alternately stacked in the first direction; a third stacked structure extending from the first stacked structure in the second direction and in which the first electrode films and the first insulating films are alternately stacked in the first direction; a first columnar body including a semiconductor layer that penetrates the first electrode films and the first insulating films in the first stacked region and forms a plurality of memory cells at intersections with the first electrode films; a plurality of contacts extending in the first direction in the second stacked region, each of the contacts reaching, in the first direction, a level of a corresponding one of the first electrode films; and a plurality of connection layers electrically connecting the contacts and the corresponding first electrode films.

Hereinafter, embodiments of the present disclosure will be described with reference to the drawings. The embodiments described below do not limit the present disclosure. In the specification and the drawings, the same elements are given the same reference numerals.

### First Embodiment

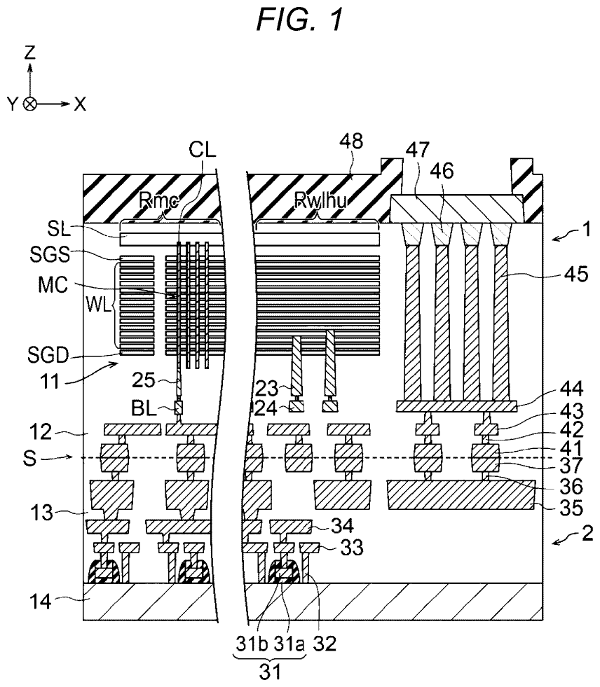

FIG. 1 is a cross-sectional view of a semiconductor memory device according to a first embodiment.

The semiconductor memory device of the present embodiment is, for example, a NAND flash memory having a memory cell array in which memory cells are arranged three-dimensionally. The semiconductor memory device of the present embodiment is manufactured by bonding an array wafer including an array chip 1 and a circuit wafer including a circuit chip 2 at a bonding surface S.

The array chip 1 includes a memory cell array 11 including a plurality of memory cells and an interlayer insulating film 12 below the memory cell array 11. The interlayer insulating film 12 is, for example, a stacked body including a silicon oxide film (for example, a SiO2 film) containing silicon and oxygen and other insulating films.

The circuit chip 2 is provided below the array chip 1. The circuit chip 2 includes an interlayer insulating film 13 below the interlayer insulating film 12, and a substrate 14 below the interlayer insulating film 13. The interlayer insulating film 13 is, for example, a stacked body including a silicon oxide film (for example, a SiO2 film) containing silicon and oxygen and other insulating films. The substrate 14 is, for example, a semiconductor substrate such as a Si (silicon) substrate.

FIG. 1 shows an X-direction and a Y-direction parallel to the surface of the substrate 14 and perpendicular to each other, and a Z-direction perpendicular to the surface of the substrate 14. The X-direction, the Y-direction, and the Z-direction intersect each other. In this specification, a +Z-direction is defined as upward, and a −Z-direction is defined as downward. The −Z-direction may or may not coincide with the direction of gravity.

The array chip 1 includes a plurality of word lines WL, a source-side selected line SGS, and a drain-side selected line SGD as a plurality of electrode films in the memory cell array 11. The source-side selected line SGS is disposed above these word lines WL, and the drain-side selected line SGD is disposed below these word lines WL. The array chip 1 includes a cell region Rmc in which the memory cell array 11 is provided, and a word line hook-up region (hereinafter also referred to as a WLHU region) Rwlhu in which word line contacts 23 are provided.

Each of the word lines WL is connected to each of the plurality of word line contacts 23, and is electrically connected to each of a plurality of word line wirings 24 via the plurality of word line contacts 23 (hereinafter, also referred to as word line contacts WLC).

A plurality of columnar bodies CL that penetrate the plurality of word lines WL, the source-side selected lines SGS, and the drain-side selected lines SGD are electrically connected to bit lines BL through via plugs 25, and are also electrically connected to source lines SL. The columnar bodies CL penetrate the stacked body of the memory cell array 11 in the Z-direction, and form a plurality of memory cells MC at the intersections with the word lines WL. The source lines SL are provided above the source-side selected lines SGS, and the bit lines BL are provided below the drain-side selected lines SGD.

Only the electrode film in the uppermost layer in FIG. 1 may be the source-side selected line SGS, but the plurality of electrode films on the uppermost side may be the source-side selected lines SGS. The number of electrode films serving as the source-side selected lines SGS may be any number. Similarly, only the electrode film at the lowermost position may be the drain-side selected line SGD, but a plurality of electrode films on the lowermost side may be the drain-side selected lines SGD. The number of electrode films serving as the drain-side selected lines SGD may be any number.

The array chip 1 further includes metal pads 41 and 47, via plugs 42, 45, and 46, wiring layers 43 and 44, and a passivation insulating film 48.

The metal pad 41 is bonded to a metal pad 37 of the circuit chip 2. The metal pad 41 is, for example, a metal layer containing Cu (copper). A complementary metal oxide semiconductor (CMOS) circuit of the circuit chip 2 is electrically connected to the memory cell array 11 via the metal pads 41 and 37, and the like, and controls the operation of the memory cell array 11. The via plug 42 is provided on the metal pad 41. The wiring layer 43 is provided on the via plug 42 and includes a plurality of wirings. The wiring layer 44 is provided on the wiring layer 43 and includes a plurality of wirings. The bit line BL is formed in the same layer as the wiring layer 44. The via plug 45 is provided on the wiring layer 44. The via plug 46 is provided on the via plug 45.

The metal pad 47 is provided on the via plug 46 and the interlayer insulating film 12. The metal pad 47 is, for example, a metal layer containing Al (aluminum) and functions as an external connection pad (for example, a bonding pad). The passivation insulating film 48 is provided on the metal pad 47 and the interlayer insulating film 12. The passivation insulating film 48 is, for example, a stacked body including a silicon oxide film (for example, a SiO2 film) containing silicon and oxygen and a silicon nitride film (for example, a SiN film) containing silicon and nitrogen, and exposes a portion of the upper surface of the metal pad 47. The metal pad 47 can be connected to a mounting substrate or other devices by a bonding wiring, a solder ball, a metal bump, or the like.

The circuit chip 2 includes a transistor 31, a contact plug 32, a wiring layer 33, a wiring layer 34, a wiring layer 35, a via plug 36, and the metal pad 37.

The transistor 31 includes a gate insulating film 31a provided on the substrate 14, a gate electrode 31b provided on the gate insulating film 31a, a source region (not shown) provided in the substrate 14, and a drain region (not shown) provided in the substrate 14.

The contact plug 32 is provided on the gate electrode 31b, the source region, and the drain region of the transistor 31. The wiring layer 33 is provided on the contact plug 32 and includes a plurality of wirings. The wiring layer 34 is provided on the wiring layer 33 and includes a plurality of wirings. The wiring layer 35 is provided on the wiring layer 34 and includes a plurality of wirings. The via plug 36 is provided on the wiring layer 35. The metal pad 37 is provided on the via plug 36. The metal pad 37 is, for example, a metal layer including a Cu layer. The circuit chip 2 includes a CMOS circuit that controls the operation of the array chip 1. The CMOS circuit includes the transistors 31 and the like, and is electrically connected to the array chip 1 via the metal pad 37.

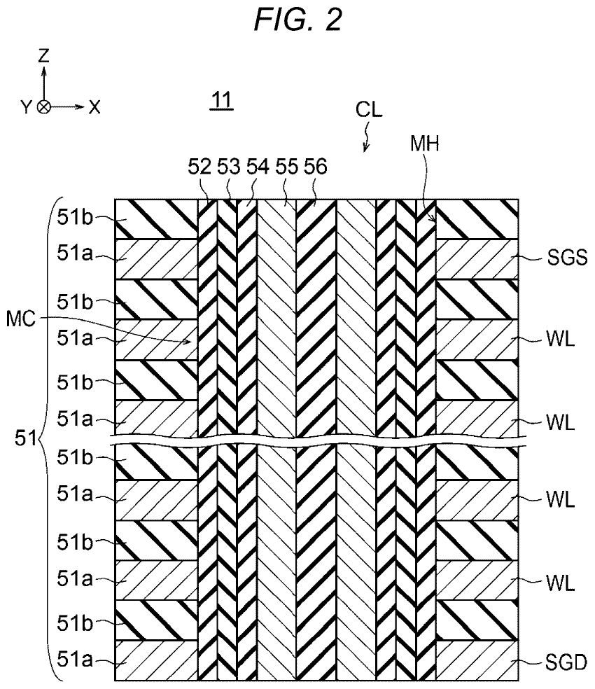

FIG. 2 is an enlarged cross-sectional view of the memory cell array 11 according to the first embodiment. FIG. 2 shows one columnar body CL.

The memory cell array 11 includes a stacked body 51 including electrode films 51a and insulating films 51b stacked alternately in the Z-direction. The electrode film 51a functions as, for example, the word line WL, the source-side selected line SGS, or the drain-side selected line SGD. In FIG. 2, the electrode film 51a at the uppermost position functions as the source-side selected line SGS, the electrode film 51a at the lowermost position functions as the drain-side selected line SGD, and the other electrode films 51a function as the word lines WL. The word line WL functions as a gate electrode of the memory cell MC. The electrode film 51a is, for example, a metal layer containing W, or Mo(tungsten, or molybdenum). The insulating film 51b is, for example, a silicon oxide film (for example, a SiO2 film) containing silicon and oxygen. The insulating film 51b is an example of a first insulating film.

The columnar body CL penetrates the stacked body 51 in the Z-direction and has a columnar shape. The columnar body CL is provided in a memory hole MH that penetrates the stacked body 51 in the Z-direction. The columnar body CL includes a block insulating film 52 provided on the inner surface of the memory hole MH, a charge storage layer 53 provided on the inner surface of the block insulating film 52, a tunnel insulating film 54 provided on the inner surface of the charge storage layer 53, a channel semiconductor layer 55 provided on the inner surface of the tunnel insulating film 54, and a core insulating film 56 provided on the inner surface of the channel semiconductor layer 55. The columnar body CL forms the memory cell MC at an intersection with the word line WL, forms a source-side select transistor at an intersection with the source-side selected line SGS, and forms a drain-side select transistor at an intersection with the drain-side selected line SGD. The memory cell MC is also referred to as a cell transistor.

The block insulating film 52 is, for example, a silicon oxide film (for example, a SiO2 film) containing silicon and oxygen. The charge storage layer 53 can store charges according to the logic of data. The charge storage layer 53 is, for example, an insulating film such as a silicon nitride film (for example, a SiN film) containing silicon and nitrogen. The tunnel insulating film 54 is, for example, a silicon oxide film (for example, a SiO2 film) containing silicon and oxygen or a silicon nitride film (for example, a SiON film) containing silicon and nitrogen. The channel semiconductor layer 55 functions as a channel of the memory cell MC. The channel semiconductor layer 55 is, for example, a film containing silicon (for example, a polysilicon layer). The core insulating film 56 is, for example, a silicon oxide film (for example, a SiO2 film) containing silicon and oxygen. The channel semiconductor layer 55 is an example of a semiconductor layer.

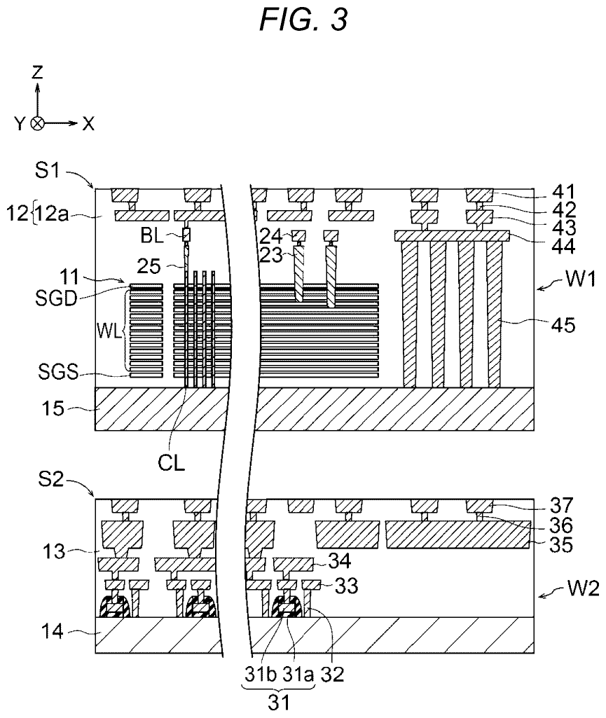

FIGS. 3 to 6 are cross-sectional views of a manufacturing process from bonding of an array wafer W1 and a circuit wafer W2 through completion of the semiconductor memory device according to the first embodiment.

FIG. 3 shows the array wafer W1 including a plurality of array chips 1 and the circuit wafer W2 including a plurality of circuit chips 2. In FIG. 3, the orientation of the array wafer W1 in the Z-direction is opposite to the orientation of the array chip 1 in the Z-direction in FIG. 1. By bonding the array wafer W1 and the circuit wafer W2 together, the array chip 1 and the circuit chip 2 are electrically connected. FIG. 3 shows the array wafer W1 before the orientation is reversed for bonding.

In the present embodiment, as shown in FIG. 3, the memory cell array 11, an interlayer insulating film 12a, the metal pads 41, the via plugs 45, and the like are formed on a substrate 15 of the array wafer W1. Separately from this, the transistor 31, the interlayer insulating film 13, the metal pads 37, and the like are formed on the substrate 14 of the circuit wafer W2. The substrates 14 and 15 are, for example, semiconductor substrates such as silicon substrates.

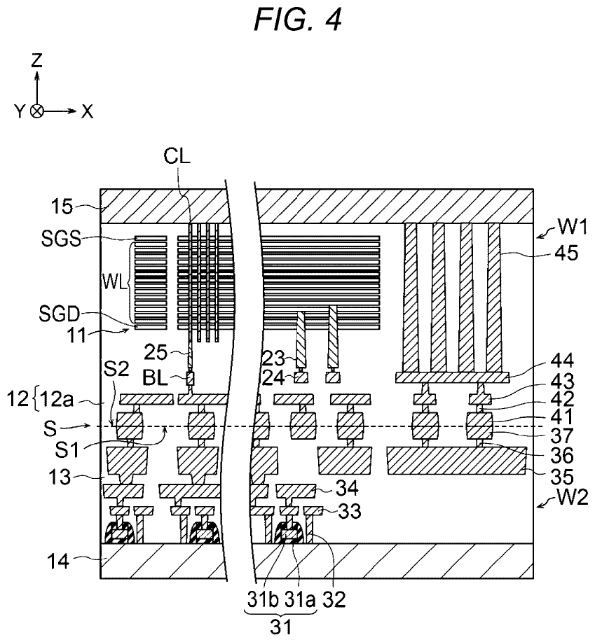

Next, as shown in FIG. 4, the array wafer W1 and the circuit wafer W2 are bonded together so that an upper surface S1 of the array wafer W1 faces an upper surface S2 of the circuit wafer W2. Thereby, the interlayer insulating film 12a and the interlayer insulating film 13 are bonded at the bonding surface S.

Next, the array wafer W1 and the circuit wafer W2 are annealed. Thereby, the metal pad 41 and the metal pad 37 are bonded together. In this manner, the array wafer W1 and the circuit wafer W2 are bonded together so that the interlayer insulating films 12a and 13 are sandwiched therebetween.

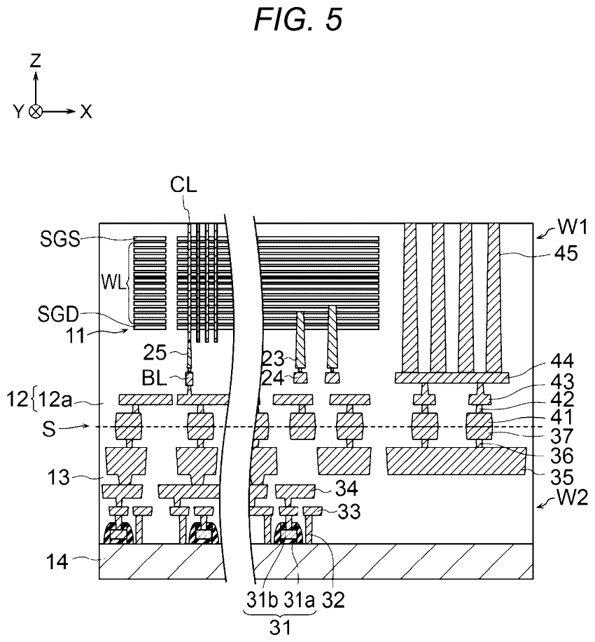

Next, as shown in FIG. 5, the substrate 15 is removed by chemical mechanical polishing (CMP) or wet etching. Thereby, the interlayer insulating film 12a, the columnar body CL, the via plug 45, and the like are exposed.

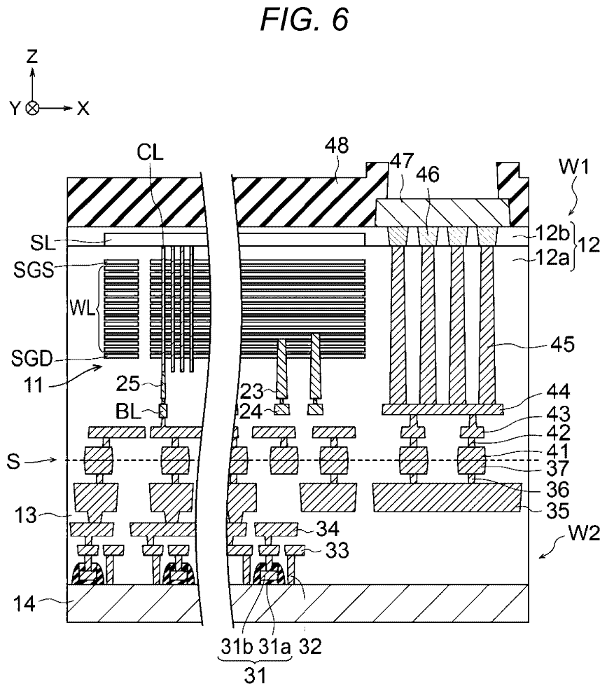

Next, as shown in FIG. 6, the source line SL is formed on the interlayer insulating film 12a and the columnar body CL, and an interlayer insulating film 12b is formed on the interlayer insulating film 12a via the source line SL.

Next, the via plug 46 penetrating the interlayer insulating film 12b is formed on the via plug 45, and the metal pad 47 is formed on the interlayer insulating film 12b and the via plug 46.

Next, the passivation insulating film 48 is formed on the interlayer insulating film 12b and the metal pad 47, and the passivation insulating film 48 is processed to expose a portion of the metal pad 47.

Thereafter, the array wafer W1 and the circuit wafer W2 are cut into a plurality of chips. In this manner, the semiconductor memory device shown in FIG. 1 is manufactured.

FIG. 1 shows a boundary surface between the interlayer insulating film 12 and the interlayer insulating film 13, and a boundary surface (bonding surface S) between the metal pad 41 and the metal pad 37, but these boundary surfaces are generally not observed after the above-described annealing. However, the positions where these boundary surfaces exist can be recognized from, for example, inclinations of the side surface of the metal pad 41 and the side surface of the metal pad 37 and a positional deviation between the side surface of the metal pad 41 and the side surface of the metal pad 37.

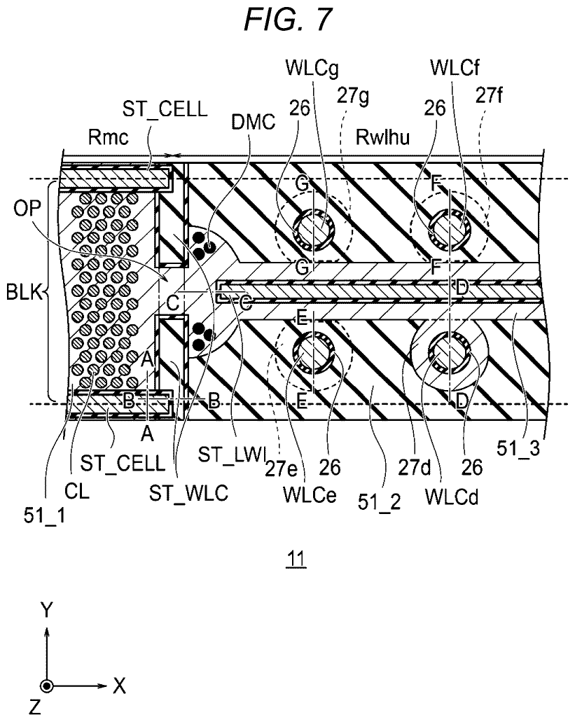

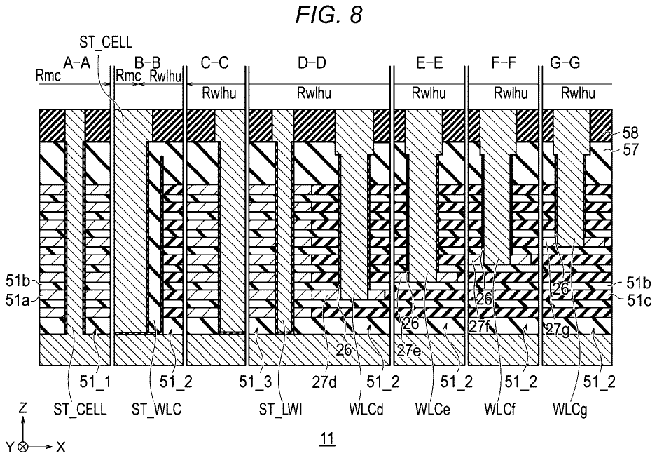

FIG. 7 is a plan view of the memory cell array 11 according to the first embodiment. FIG. 8 is a cross-sectional view of the memory cell array 11 according to the first embodiment. FIG. 7 shows an end of the memory cell array 11. Line A-A in FIG. 8 indicates a cross section taken along line A-A in FIG. 7. Line B-B in FIG. 8 indicates a cross section taken along line B-B in FIG. 7. Line C-C in FIG. 8 indicates a cross section taken along line C-C in FIG. 7. Line D-D in FIG. 8 indicates a cross section taken along line D-D in FIG. 7. Line E-E in FIG. 8 indicates a cross section taken along line E-E in FIG. 7. Line F-F in FIG. 8 indicates a cross section taken along line F-F in FIG. 7. Line G-G in FIG. 8 indicates a cross section taken along line G-G in FIG. 7.

As shown in FIG. 7, the memory cell array 11 has the cell region Rmc and the WLHU region Rwlhu.

A first stacked body 51_1 is provided in the cell region Rmc of the stacked body 51. As shown in FIG. 8, the first stacked body 51_1 is formed by alternately stacking the electrode films 51a and the insulating films 51b in the Z-direction. As shown in FIG. 7, the first stacked body 51_1 is provided with a plurality of columnar bodies CL. In addition, the first stacked body 51_1 is provided with a plurality of slits ST_CELL.

The slits ST_CELL penetrate the first stacked body 51_1 in the Z-direction as shown in FIG. 8 and extend in the X-direction as shown in FIG. 7. The slits ST_CELL divide the first stacked body 51_1 into a plurality of blocks BLK. The portion of the first stacked body 51_1 sandwiched between two slits ST_CELL is referred to as the block BLK. The block BLK is, for example, a unit of data erasure. The slit ST_CELL electrically separates the first stacked body 51_1 for each block BLK.

An inner wall of the slit ST_CELL is covered with an insulating film such as a silicon oxide film, and a conductive material is further embedded inside the insulating film. The conductive material is connected to the source line SL and can function as a source wiring. When it is not used as a source line, the slit ST_CELL may be filled with an insulating film such as a silicon oxide film (for example, SiO2 film) containing silicon and oxygen.

The WLHU region Rwlhu of the stacked body 51 is provided adjacent to the cell region Rmc. A second stacked body 51_2 and a third stacked body 51_3 are provided in the WLHU region Rwlhu.

As shown in FIG. 8, the second stacked body 51_2 is formed by alternately stacking the insulating films 51b (for example, silicon oxide films) and insulating films 51c (for example, silicon nitride films) in the Z-direction. As shown in FIG. 7, the second stacked body 51_2 is adjacent to the first stacked body 51_1 with the slit ST_WLC sandwiched therebetween. In addition, the second stacked body 51_2 is adjacent to the third stacked body 51_3. The second stacked body 51_2 is provided with a plurality of word line contacts WLC.

As shown in FIG. 8, the slit ST_WLC penetrates the first or second stacked body 51_1 or 51_2 in the Z-direction between the first stacked body 51_1 and the second stacked body 51_2. As shown in FIG. 7, the slit ST_WLC extends intermittently in the Y-direction in the X-Y plane. The slit ST_WLC is filled with an insulating film (for example, a silicon oxide film). Thereby, the first stacked body 51_1 and the second stacked body 51_2 are physically separated from each other, and the insulating film 51c of the second stacked body 51_2 in the WLHU region Rwlhu is prevented from being replaced with the conductive material of the electrode film 51a. On the other hand, the slit ST_WLC has an opening OP for connecting a portion of the first stacked body 51_1 in the cell region Rmc to the third stacked body 51_3 in the WLHU region Rwlhu for each block BLK.

As shown in FIG. 8, the third stacked body 51_3 is formed by alternately stacking the electrode films 51a (for example, tungsten, molybdenum) and the insulating films 51b (for example, silicon oxide films) in the Z-direction. As shown in FIG. 7, the third stacked body 51_3 is connected to the first stacked body 51_1 from the end of the first stacked body 51_1 through the opening OP, and extends in the +X-direction from the end of the first stacked body 51_1 in the X-Y plane. The electrode films 51a and the insulating films 51b of the third stacked body 51_3 are continuously connected to those of the first stacked body 51_1 in each layer. Furthermore, a dummy columnar body DMC is provided at the end of the third stacked body 51_3 on the cell region Rmc side. The dummy columnar body DMC is formed at the same time as the columnar body CL in the first stacked body, but does not function as a memory cell. The dummy columnar body DMC prevents the insulating film 51b at the connection between the first stacked body 51_1 and the third stacked body 51_3 from bending due to its own weight when the insulating film 51c of the first and third stacked bodies 51_1 and 51_3 is replaced with the conductive material of the electrode film 51a. Furthermore, the third stacked body 51_3 is provided with a slit ST_LWI. The dummy columnar body DMC may be disposed around the slit ST_LWI to prevent bending.

As shown in FIG. 8, the slit ST_LWI penetrates the third stacked body 51_3 in the Z-direction in the third stacked body 51_3. As shown in FIG. 7, the slit ST_LWI extends in the X-direction along the extension direction of the third stacked body 51_3 in the X-Y plane. The inner wall of the slit ST_LWI is covered with an insulating film such as a silicon oxide film, and a conductive material is further embedded inside the insulating film. Thereby, the slit ST_LWI can be formed at the same time as the slit ST_CELL. However, the conductive material does not need to be connected to the source line SL. Thus, alternatively, the slit ST_LWI may be filled with an insulating film such as a silicon oxide film.

As shown in FIG. 7, the plurality of word line contacts WLC extend in the Z-direction in the second stacked body 51_2. As shown in FIG. 8, the plurality of word line contacts WLC are provided to the depth of each of the plurality of electrode films 51a (that is, word lines WL).

The word line contact WLC is embedded inside a spacer 26 (for example, silicon oxide film) provided on the inner wall of the contact hole. For example, tungsten is used for the word line contact WLC.

For example, in the cross section taken along line D-D in FIG. 7, as shown in FIG. 8, a word line contact WLCd extends to the electrode film 51a which is the second layer from the bottom of the first or third stacked body 51_1 or 51_3, and is not provided below that in the −Z-direction. The word line contact WLCd is electrically connected to the electrode film 51a which is the second layer from the bottom via a connect layer 27d. The word line contact WLCd is electrically insulated from the electrode films 51a other than the electrode film 51a which is the second layer from the bottom by the spacer 26 and the insulating film 51c.

In the cross section taken along line E-E in FIG. 7, as shown in FIG. 8, a word line contact WLCe extends to the electrode film 51a which is the third layer from the bottom of the first or third stacked body 51_1 or 51_3, and is not provided below that in the −Z-direction. The word line contact WLCe is electrically connected to the electrode film 51a which is the third layer from the bottom via a connect layer 27e. The word line contact WLCe is electrically insulated from the electrode films 51a other than the electrode film 51a which is the third layer from the bottom by the spacer 26 and the insulating film 51c.

In the cross section taken along line F-F in FIG. 7, as shown in FIG. 8, a word line contact WLCf extends to the electrode film 51a which is the fourth layer from the bottom of the first or third stacked body 51_1 or 51_3, and is not provided below that in the −Z-direction. The word line contact WLCf is electrically connected to the electrode film 51a which is the fourth layer from the bottom via a connect layer 27f. The word line contact WLCf is electrically insulated from the electrode films 51a other than the electrode film 51a which is the fourth layer from the bottom by the spacer 26 and the insulating film 51c.

In the cross section taken along line G-G in FIG. 7, as shown in FIG. 8, a word line contact WLCg extends to the electrode film 51a which is the fifth layer from the bottom of the first or third stacked body 51_1 or 51_3, and is not provided below that in the −Z-direction. The word line contact WLCg is electrically connected to the electrode film 51a which is the fifth layer from the bottom via a connect layer 27g. The word line contact WLCg is electrically insulated from the electrode films 51a other than the electrode film 51a which is the fifth layer from the bottom by the spacer 26 and the insulating film 51c.

Although not shown in the drawing, the other word line contacts WLC are also provided to their respective depths in the other electrode films 51a, and are electrically connected to the corresponding electrode films 51a.

In this manner, each word line contact WLC is electrically connected to the corresponding electrode film 51a via one connect layer 27.

The plurality of connect layers 27 are provided between the plurality of word line contacts WLC and the plurality of corresponding electrode films 51a, and electrically connect them. The connect layer 27 is formed by isotropically etching the second insulating film 51c from the bottom of each word line contact WLC. Thus, the connect layers 27 spread substantially evenly from the bottom of each word line contact WLC to its periphery. The connect layer 27 is made of a conductive material such as tungsten or molybdenum.

For example, the connect layer 27d is provided between the word line contact WLCd and the electrode film 51a which is the second layer from the bottom of the first or third stacked body 51_1 or 51_3, and electrically connects them. The connect layer 27d is not provided in any layer other than the electrode film 51a which is the second layer from the bottom.

The connect layer 27e is provided between the word line contact WLCe and the electrode film 51a which is the third layer from the bottom of the first or third stacked body 51_1 or 51_3, and electrically connects them. The connect layer 27e is not provided in any layer other than the electrode film 51a which is the third layer from the bottom.

The connect layer 27f is provided between the word line contact WLCf and the electrode film 51a which is the fourth layer from the bottom of the first or third stacked body 51_1 or 51_3, and electrically connects them. The connect layer 27f is not provided in any layer other than the electrode film 51a which is the fourth layer from the bottom.

The connect layer 27g is provided between the word line contact WLCg and the electrode film 51a which is the fifth layer from the bottom of the first or third stacked body 51_1 or 51_3, and electrically connects them. The connect layer 27g is not provided in any layer other than the electrode film 51a which is the fifth layer from the bottom.

As shown in FIG. 8, interlayer insulating films 57 and 58 are provided on the first to third stacked bodies 51_1 to 51_3. For example, insulating films (for example, silicon oxide films) are used for the interlayer insulating films 57 and 58. The slits ST_CELL, ST_WLC, and ST_LWI and the word line contacts WLC extend to penetrate the interlayer insulating films 57 and 58 in the Z-direction.

In this manner, according to the first embodiment, the plurality of word line contacts WLC are provided to the depth of each of the plurality of electrode films 51a in the second stacked body 51_2, and are electrically connected to the electrode film 51a corresponding to each of the third stacked bodies 51_3 via the connect layer 27.

The plurality of electrode films 51a of the first stacked body 51_1 respectively correspond to and are electrically connected to the plurality of electrode films 51a of the third stacked body 51_3. In addition, the plurality of insulating films 51b of the first stacked body 51_1 respectively correspond to the plurality of insulating films 51b of the third stacked body 51_3, and electrically separate the electrode films 51a adjacent to each other in the Z-direction. Thereby, the plurality of word line contacts WLC can be electrically connected to the plurality of electrode films 51a of the first and third stacked bodies 51_1 and 51_3, respectively, while maintaining an electrical insulation state of each other.

Meanwhile, the second stacked body 51_2 includes first and second insulating films 51b and 51c. The plurality of first insulating films 51b of the second stacked body 51_2 correspond to the plurality of first insulating films 51b of the first and third stacked bodies 51_1 and 51_3, respectively. The plurality of second insulating films 51c of the second stacked body 51_2 correspond to the plurality of electrode films 51a of the first and third stacked bodies 51_1 and 51_3, respectively. Thus, in the WLHU region Rwlhu, the plurality of word line contacts WLC are electrically isolated from the electrode films 51a and the connect layers 27 other than the electrode films 51a and the connect layers 27 corresponding to them.

Thereby, voltages can be applied separately from the word line contacts WLC to the electrode films 51a (i.e., the word lines WL).

Further, in a manufacturing process to be described below, when the second insulating films 51c of the first and third stacked bodies 51_1 and 51_3 are replaced with the electrode films 51a, the second insulating film 51c of the second stacked body 51_2 is left without being replaced. Thereby, it is possible to prevent the first insulating film 51b from bending or being depressed due to its own weight without the need to provide a support pillar in the WLHU region Rwlhu.

In FIG. 7, one block BLK is provided with one opening OP and one slit ST_LWI. However, one block BLK may be provided with a plurality of openings OP and a plurality of slits ST_LWI. In this case, word line contacts WLC may be provided around each slit ST_LWI.

Next, a manufacturing method for the semiconductor memory device according to the present embodiment will be described.

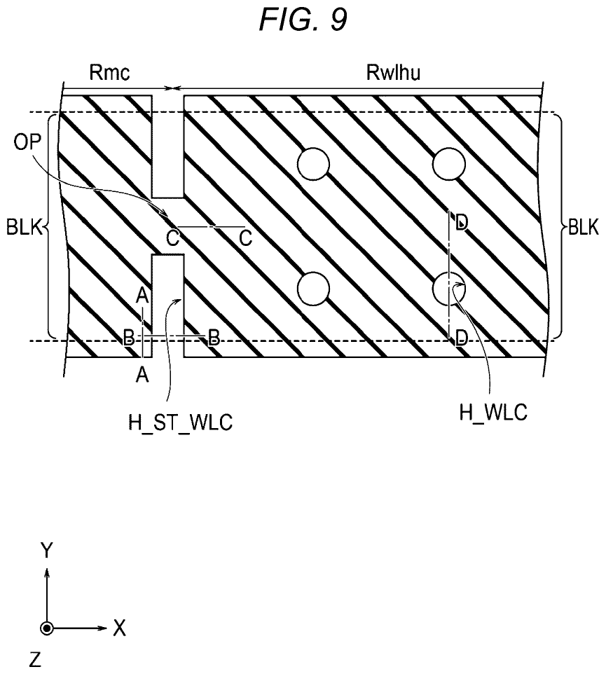

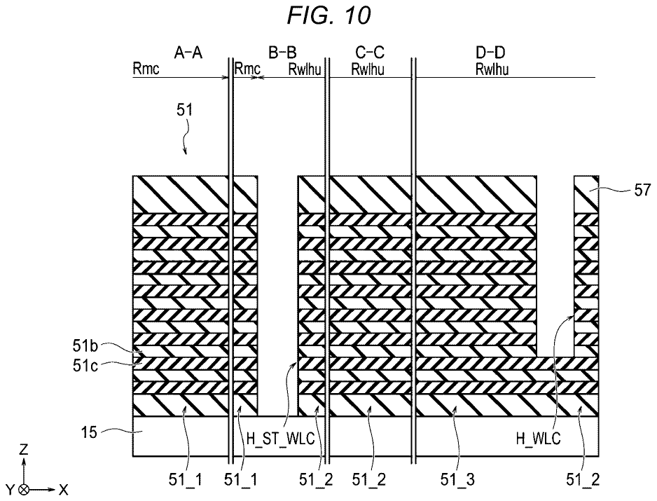

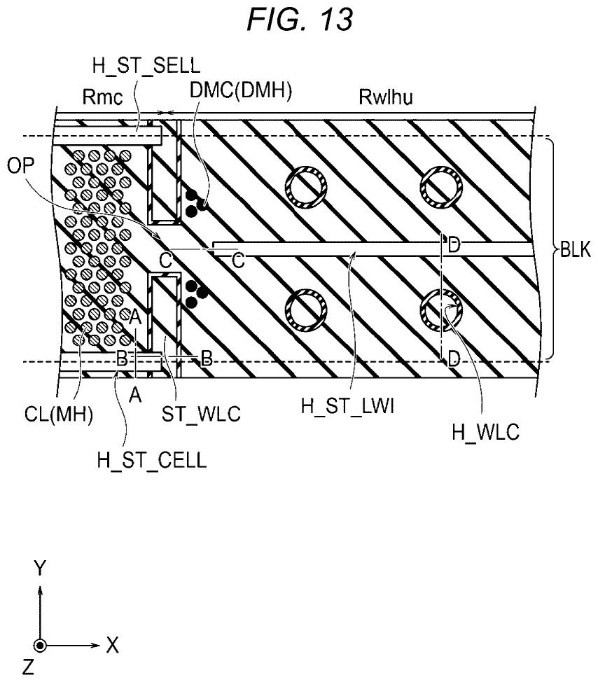

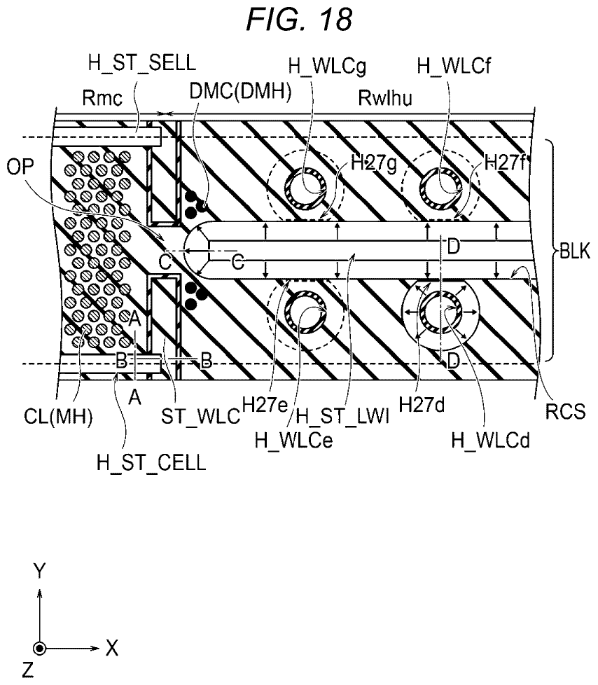

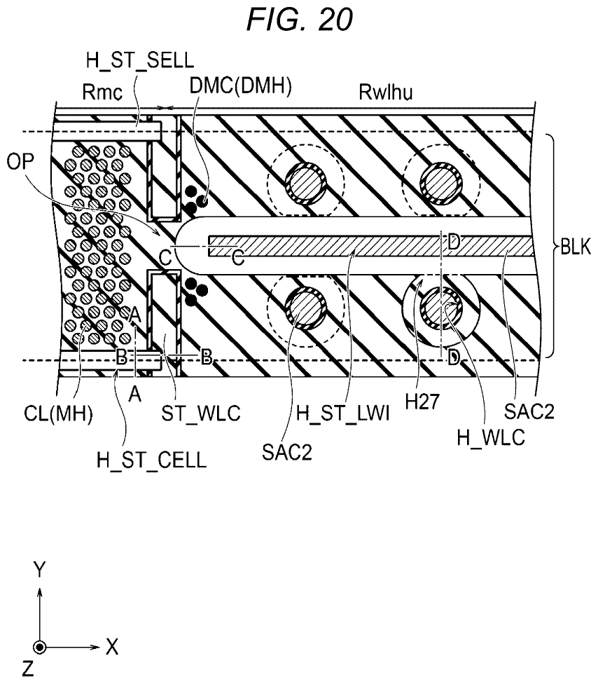

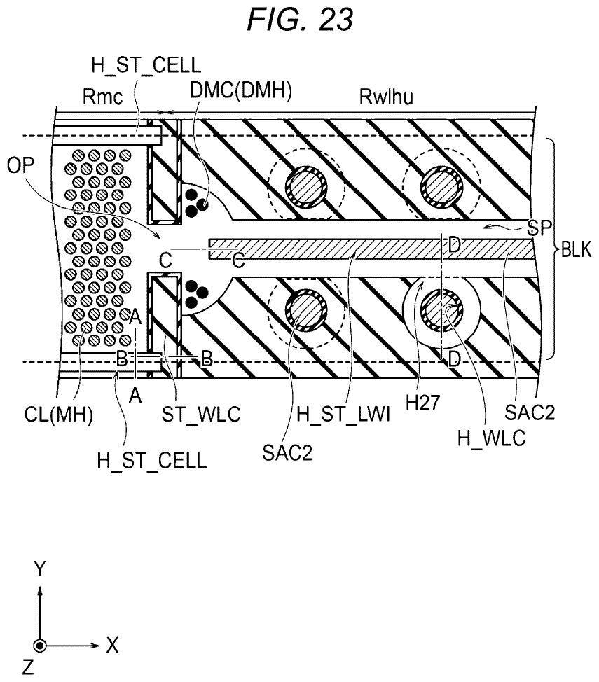

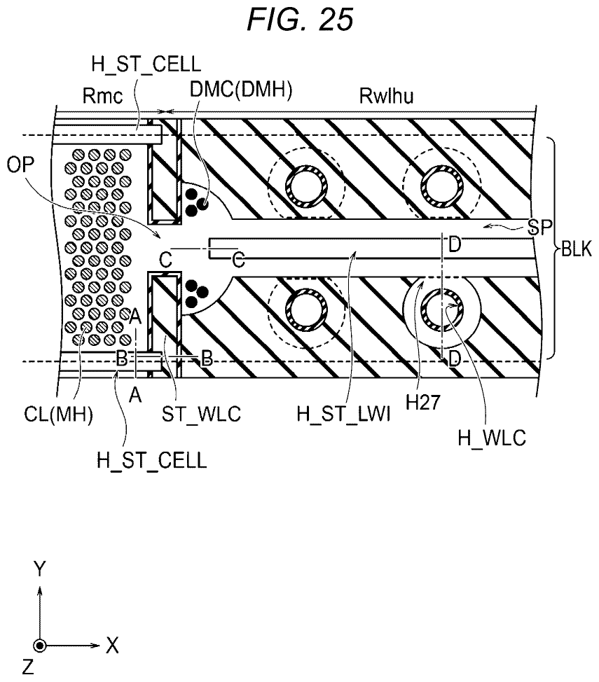

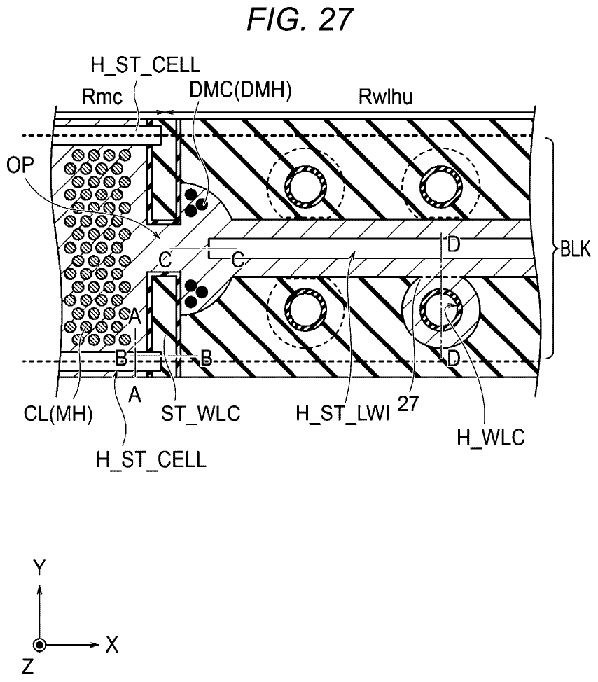

FIGS. 9 to 31 are diagrams of a manufacturing method for the semiconductor memory device according to the first embodiment. FIG. 9, FIG. 13, FIG. 18, FIG. 20, FIG. 23, FIG. 25, and FIG. 27 show the plane of the memory cell array 11. FIGS. 10 to 12, FIGS. 14 to 17, FIG. 19, FIG. 21, FIG. 22, FIG. 24, FIG. 26, and FIGS. 28 to 31 show the cross section of the memory cell array 11.

The cross sections taken along lines A-A, B-B, C-C, and D-D in the plan views of FIG. 9 and the like are respectively shown as A-A, B-B, C-C, and D-D in the cross sections of FIG. 10 and the like. Structures corresponding to the cross sections taken along lines E-E, F-F, and G-G in FIG. 7 are not shown in FIG. 10 and the like.

As shown in FIG. 10, the first insulating films 51b (for example, silicon oxide films) and the second insulating films 51c (for example, silicon nitride films) are alternately stacked on the substrate 15 in the Z-direction to form the stacked body 51. Furthermore, the interlayer insulating film 57 (for example, a silicon oxide film) is deposited on the stacked body 51.

Next, a slit hole (trench) H_ST_WLC of the slit ST_WLC and a contact hole H_WLC of the word line contact WLC are formed using lithography and etching techniques. The slit hole H_ST_WLC is provided between the cell region Rmc and the WLHU region Rwlhu. As shown in FIG. 9, the slit hole H_ST_WLC has the opening OP so as to connect a portion of the cell region Rmc to the WLHU region Rwlhu while separating the cell region Rmc from the WLHU region Rwlhu. As shown in FIG. 10, the contact hole H_WLC is formed in the WLHU region Rwlhu to the second insulating film 51c corresponding to the depth of the electrode film 51a to which it is electrically connected. The plurality of contact holes H_WLC are formed to the second insulating films 51c having different depths. The first stacked body 51_1 and the third stacked body 51_3 are each include a stacked body including a plurality of first insulating films 51b and a plurality of second insulating films 51c.

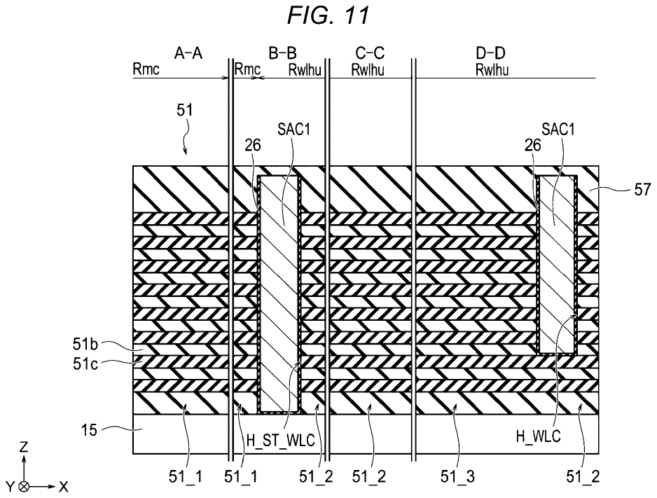

Next, as shown in FIG. 11, the spacer 26 (for example, a silicon oxide film) is formed on the inner wall of each of the slit hole H_ST_WLC and the contact hole H_WLC. Next, a sacrificial film SAC1 is embedded inside the spacer 26 in each of the slit hole H_ST_WLC and the contact hole H_WLC. The sacrificial film SAC1 is made of a material (for example, polysilicon, carbon) that can be etched with respect to the spacer 26 and the stacked body 51. Next, the stacked body 51 is covered with the silicon oxide film 57 so that the upper ends of the slit hole H_ST_WLC and the contact hole H_WLC are not exposed to the outside.

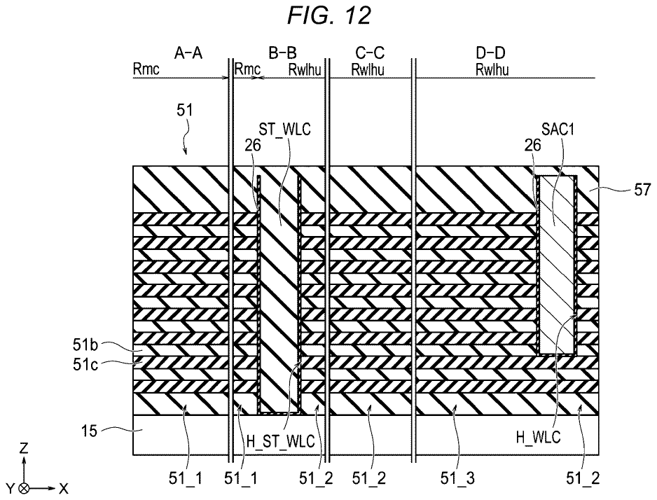

Next, the interlayer insulating film 57 on the slit hole H_ST_WLC is removed using lithography and etching techniques, the sacrificial film SAC1 in the slit hole H_ST_WLC is selectively removed, and an insulating film (for example, a silicon oxide film) is embedded in the slit hole H_ST_WLC. Thereby, the slit ST_WLC is formed as shown in FIG. 12.

Next, as shown in FIG. 13, a plurality of memory holes MH are formed to penetrate the stacked body 51 in the Z-direction in the cell region Rmc of the stacked body 51. Next, the block insulating film 52, the charge storage layer 53, the tunnel insulating film 54, the channel semiconductor layer 55, and the core insulating film 56 shown in FIG. 2 are formed on the inner wall of the memory hole MH in this order. Thereby, the columnar body CL is formed in the memory hole MH.

At the same time as when the memory hole MH is formed, a dummy hole DMH is formed near the opening OP in the WLHU region Rwlhu. The dummy hole DMH also penetrates the stacked body 51 in the Z-direction. In addition, at the same time when the columnar body CL is formed, the block insulating film 52, the charge storage layer 53, the tunnel insulating film 54, the channel semiconductor layer 55, and the core insulating film 56 are formed on the inner wall of the dummy hole DMH in this order. Thereby, the dummy columnar body DMC is formed in the dummy hole DMH. The dummy columnar body DMC is a columnar body having the same structure as the columnar body CL, but does not function as a memory cell. The dummy columnar body DMC is provided to support the first insulating film 51b near the opening OP in a replacement process to be described below.

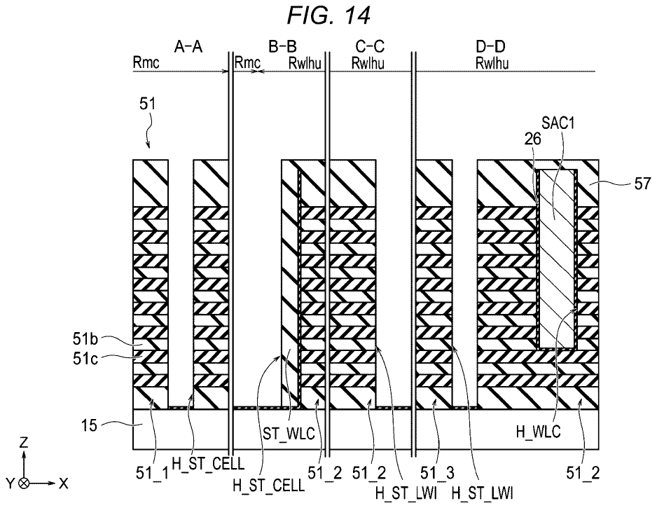

Next, as shown in FIGS. 13 and 14, the slit hole H_ST_CELL for the slit ST_CELL and the slit hole H_ST_LWI for the slit ST_LWI are formed using lithography and etching techniques. The slit hole H_ST_CELL penetrates the cell region Rmc of the stacked body 51 in the Z-direction and extends in the X-direction in the X-Y plane. The slit hole H_ST_LWI penetrates the WLHU region Rwlhu of the stacked body 51 in the Z-direction and extends in the X-direction in the X-Y plane.

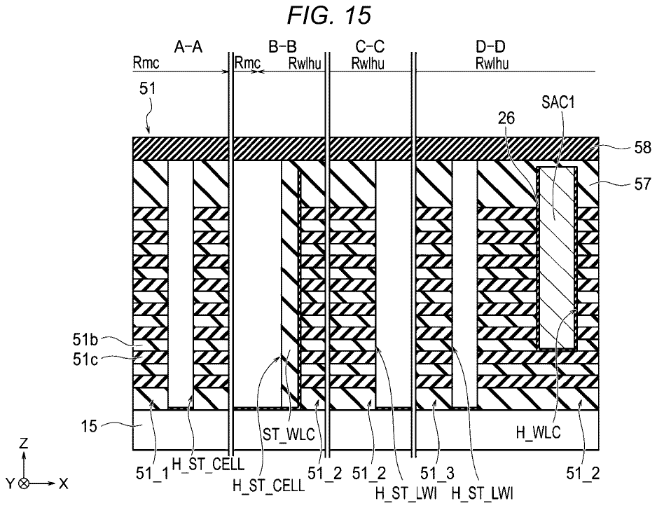

Next, the insulating film 58 is deposited on the insulating film 57 under poor coverage conditions using a plasma chemical vapor deposition (CVD) method or the like. As shown in FIG. 15, the insulating film 58 is formed to close the openings of the slit holes H_ST_CELL and H_ST_WLI without filling them.

Next, the insulating films 57 and 58 on the contact holes H_WLC are removed using lithography and etching techniques to expose the surface of the sacrificial film SAC1.

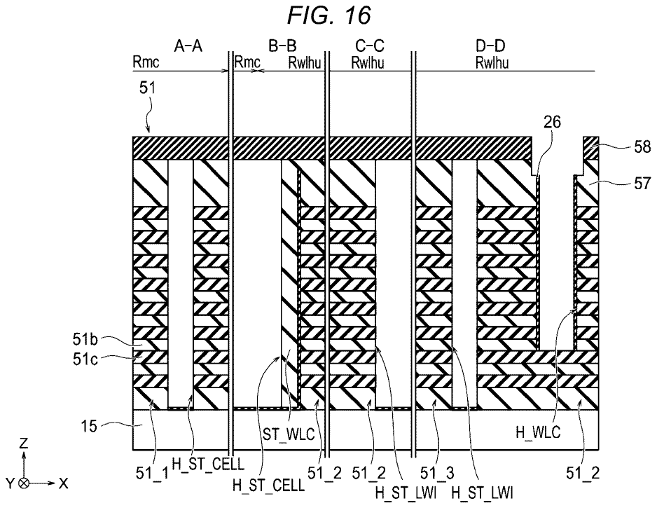

Next, as shown in FIG. 16, the sacrificial film SAC1 in the contact hole H_WLC is selectively removed using a wet etching method, an ashing method or the like, and the spacer 26 at the bottom of the contact hole H_WLC is removed by anisotropic etching. Thereby, the spacer 26 at the bottom is removed while leaving the spacer 26 on the sidewall of each contact hole H_WLC, and the second insulating film 51c is exposed at the bottom.

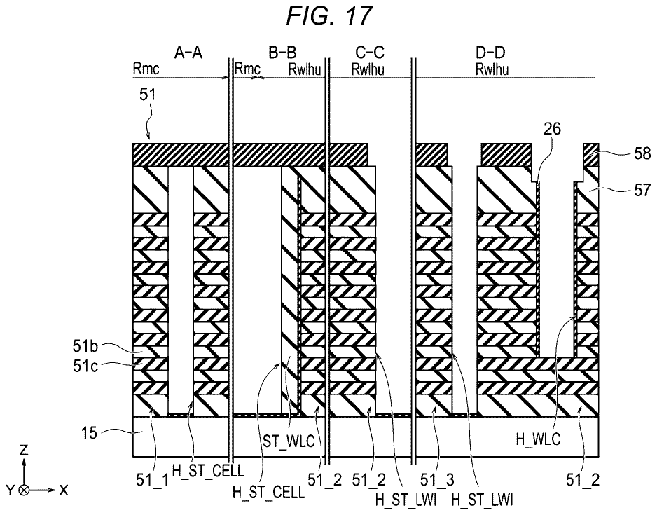

Next, as shown in FIG. 17, the insulating film 58 on the slit hole H_ST_LWI is removed using lithography and etching techniques.

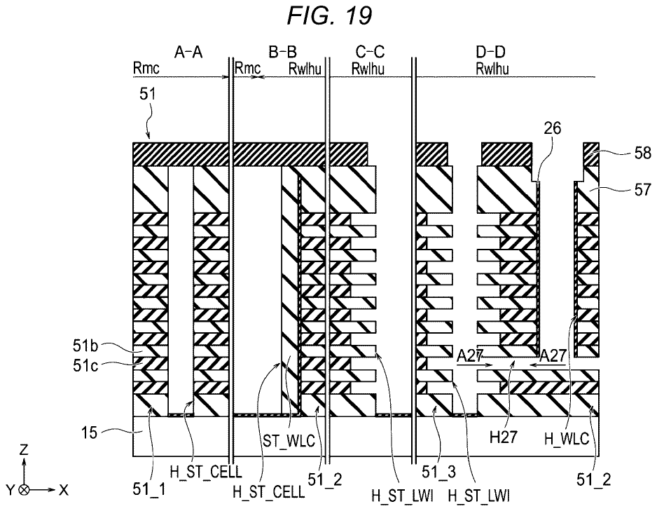

Next, as shown in FIGS. 18 and 19, the second insulating film 51c of the stacked body 51 in the WLHU region Rwlhu is isotropically etched through the contact hole H_WLC and the slit hole H_ST_LWI using wet etching or chemical dry etching (CDE) method. Thereby, the second insulating film 51c is recessed in the X-Y plane. As shown by arrows in FIG. 18, the second insulating films 51c of the stacked body 51 are recessed through the slit hole H_ST_LWI to form a recess region RCS. At this time, the second insulating film 51c exposed at the bottom of the contact hole H_WLC is etched from the contact hole H_WLC side and is also etched from the slit hole H_ST_LWI side. That is, as shown by arrows A27 in FIG. 19, the second insulating film 51c exposed at the bottom of the contact hole H_WLC is etched from both the contact hole H_WLC side and the slit hole H_ST_LWI side. Thereby, the contact hole H_WLC and the slit hole H_ST_LWI communicate with each other via a cavity H27.

The inner wall of the contact hole H_WLC other than the bottom is protected by the spacer 26. Thus, the second insulating film 51c is not exposed at the inner wall of the contact hole H_WLC and is not etched. Thus, the contact hole H_WLC and the slit hole H_ST_LWI communicate with each other in the layer of the second insulating film 51c exposed at the bottom of the contact hole H_WLC, but do not communicate with each other in the other layers of the second insulating film 51c.

Although not shown in FIG. 19, the same is true for the other contact holes H_WLC. For example, in FIG. 18, for the sake of convenience, four contact holes are indicated as H_WLCd to H_WLCg, and four corresponding cavities are indicated as H27d to H27g. The contact hole H_WLCd communicates with the slit hole H_ST_LWI via the cavity H27d in the second insulating film 51c which is the second layer from the bottom of the stacked body 51. The contact hole H_WLCe communicates with the slit hole H_ST_LWI via the cavity H27e in the second insulating film 51c which is the third layer from the bottom of the stacked body 51. The contact hole H_WLCf communicates with the slit hole H_ST_LWI via the cavity H27f in the second insulating film 51c which is the fourth layer from the bottom of the stacked body 51. The contact hole H_WLCg communicates with the slit hole H_ST_LWI via the cavity H27g in the second insulating film 51c which is the fifth layer from the bottom of the stacked body 51.

In this manner, the contact hole H_WLC and the slit hole H_ST_LWI communicate with each other in the second insulating films 51c having different depths and exposed at the bottom of each contact hole H_WLC, but do not communicate with each other in the second insulating films 51c of the other layers. Thereby, the plurality of contact holes H_WLC communicate with the slit holes H_ST_LWI via the cavities H27 in the second insulating films 51c of different layers.

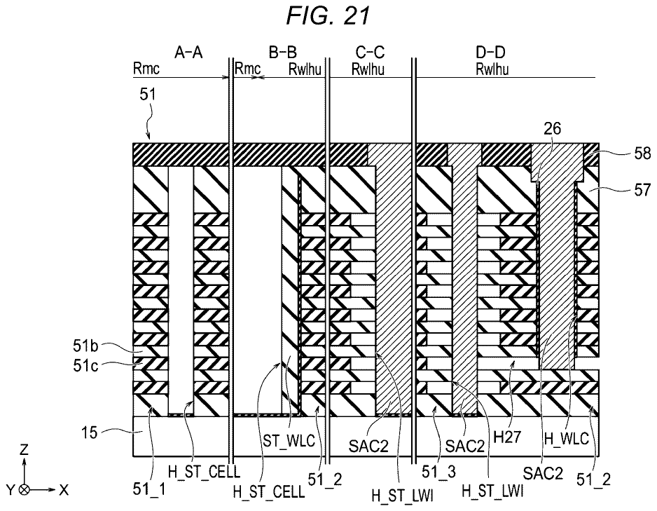

Next, as shown in FIGS. 20 and 21, a sacrificial film SAC2 is formed in the contact hole H_WLC and the slit hole H_ST_LWI. The sacrificial film SAC2 is made of a material (for example, polysilicon, carbon) that can be selectively etched with respect to the spacer 26 and the stacked body 51.

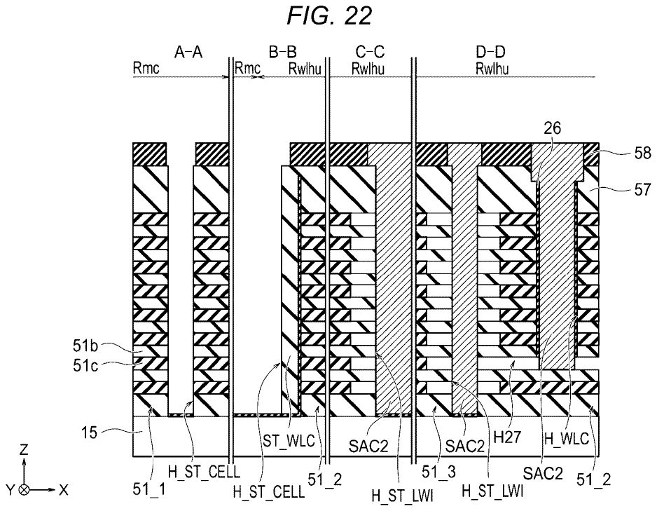

Next, the interlayer insulating film 58 on the slit hole H_ST_CELL is removed using lithography and etching techniques, as shown in FIG. 22.

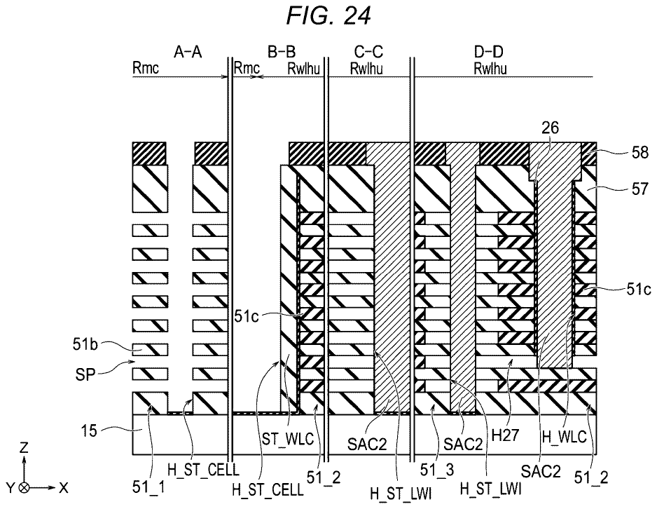

Next, as shown in FIGS. 23 and 24, the second insulating film 51c of the stacked body 51 in the cell region Rmc is isotropically etched through the slit hole H_ST_CELL by using wet etching or a CDE method. Thereby, as shown in FIG. 23, the plurality of second insulating films 51c in the cell region Rmc are removed in the X-Y plane through the slit holes H_ST_CELL. In the cell region Rmc, the second insulating film 51c around the columnar body CL is removed.

The etching of the second insulating film 51c is stopped at the slit ST_WLC. However, the etching of the second insulating film 51c proceeds from the opening OP toward the WLHU region Rwlhu and reaches the slit hole H_ST_LWI. Thereby, as shown in FIG. 23, the slit hole H_ST_CELL communicates with the slit hole H_ST_LWI and the contact hole H_WLC through the opening OP. At this time, the slit hole H_ST_LWI and the contact hole H_WLC are filled with the sacrificial film SAC2.

As shown in FIG. 24, a space SP is formed at a location where the second insulating film 51c is provided. At this time, in the cell region Rmc, the columnar bodies CL support the first insulating film 51b, and thus the first insulating film 51b can be prevented from bending or being depressed. Further, in the WLHU region Rwlhu, no support pillar is provided except for the dummy columnar body DMC. However, in the WLHU region Rwlhu other than the vicinity of the slit hole H_ST_LWI and the contact hole H_WLC, the second insulating film 51c is left, and no space SP is formed. Thus, in the WLHU region Rwlhu, even when there is no support pillar, the stacked body 51 can be prevented from bending or being depressed.

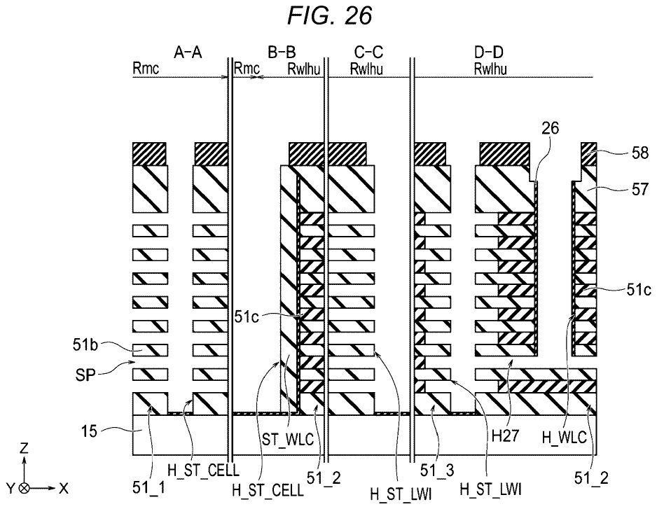

Next, as shown in FIGS. 25 and 26, the sacrificial film SAC2 is selectively removed using a wet etching method, an ashing method, or the like. Thereby, the slit hole H_ST_CELL communicates with the slit hole H_ST_LWI through the space SP in each layer formed by removing the plurality of second insulating films 51c.

Next, a thin block insulating film (for example, an aluminum oxide film) (not shown) is formed on the inner wall of the space SP formed between the first insulating films 51b through the contact hole H_WLC, the slit hole H_ST_CELL, and the slit hole H_ST_LWI. Furthermore, a titanium nitride film (not shown) is formed inside the block insulating film, and a conductive material is embedded therein. For example, tungsten, molybdenum, and the like are used as the conductive material. Thereby, the electrode film 51a is formed between the first insulating films 51b adjacent to each other in the Z-direction. The first and third stacked bodies 51_1 and 51_3 are stacked bodies including a plurality of first insulating films 51b and a plurality of electrode films 51a. The second stacked body 51_2 is a stacked body including a plurality of first insulating films 51b and a plurality of second insulating films 51c. In this manner, in the first and third stacked bodies 51_1 and 51_3, the second insulating film 51c is replaced with the electrode film 51a (hereinafter referred to as a replacement process).

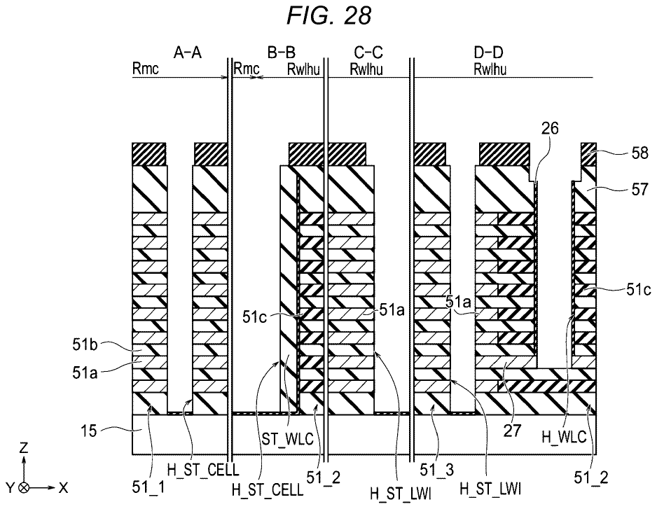

Next, the material of the electrode film 51a formed on the inner walls of the contact hole H_WLC, the slit hole H_ST_CELL, and the slit hole H_ST_LWI is etched by a wet etching method to remove a short-circuit path between the electrode films 51a adjacent to each other in the Z-direction, thereby obtaining the structure shown in FIGS. 27 and 28.

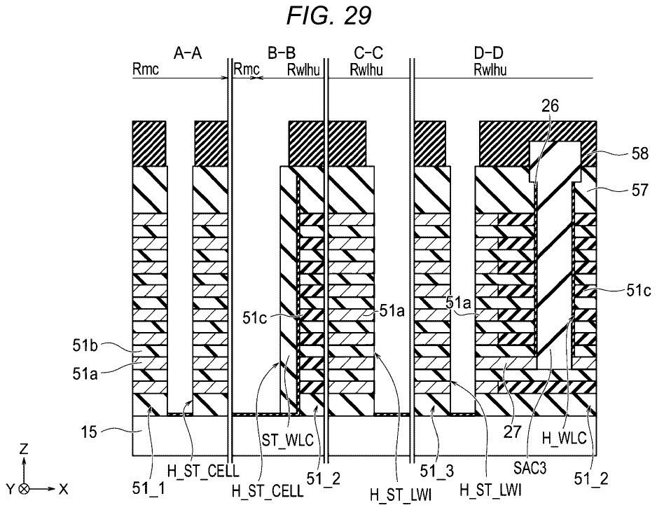

Next, the contact hole H_WLC, the slit hole H_ST_CELL, and the slit hole H_ST_LWI are filled with a sacrificial film SAC3 such as polysilicon or carbon. Next, the upper portion of the sacrificial film SAC3 is removed by an etch-back method using CMP or RIE, and then the interlayer insulating film 58 is deposited on the surface thereof. Thereafter, the interlayer insulating film 58 on the slit hole H_ST_CELL and the slit hole H_ST_LWI is removed using a lithography technique, and the sacrificial film SAC3 in the slit hole H_ST_CELL and the slit hole H_ST_LWI is selectively removed by a wet etching method, an ashing method, or the like. At this time, the sacrificial film SAC3 is left in the contact hole H_WLC, thereby obtaining the structure shown in FIG. 29.

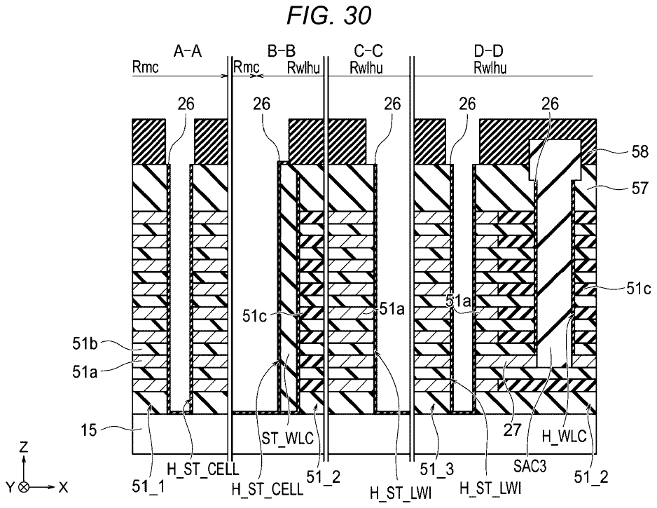

Next, as shown in FIG. 30, the spacer 26 is formed on the inner wall of the slit hole H_ST_CELL and the slit hole H_ST_LWI.

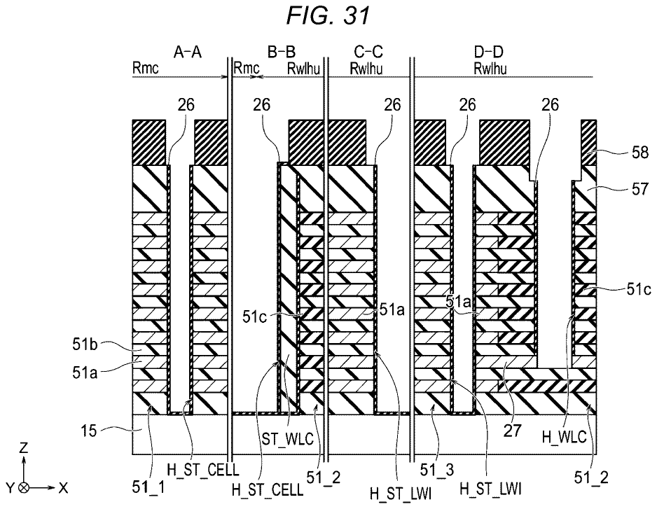

Next, the interlayer insulating film 58 on the contact hole H_WLC is removed using lithography and etching techniques to expose the sacrificial film SAC3. Next, the sacrificial film SAC3 is removed using a wet etching method, an ashing method, or the like as shown in FIG. 31.

Next, a conductive material is embedded in the contact hole H_WLC, the slit hole H_ST_CELL, and the slit hole H_ST_LWI. Thereby, the structure shown in FIGS. 7 and 8 is obtained.

Thereafter, a multilayer wiring layer (not shown) and the like are formed on the interlayer insulating film 58, and the semiconductor memory device according to the present embodiment is completed through the processes described with reference to FIGS. 3 to 6.

According to the manufacturing method of the present embodiment, when the second insulating films 51c of the first and third stacked bodies 51_1 and 51_3 are replaced with the electrode films 51a, the second insulating film 51c of the second stacked body 51_2 is left without being replaced. Thereby, it is possible to prevent the first insulating film 51b from bending or being depressed due to its own weight in the WLHU region Rwlhu without the need to provide a support pillar.

### Second Embodiment

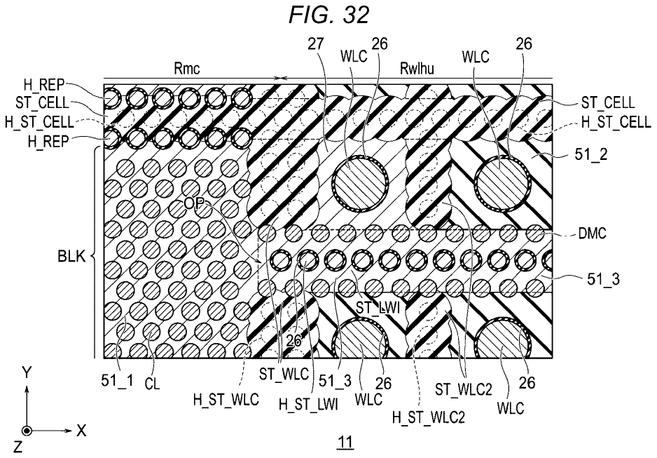

FIG. 32 is a plan view of the memory cell array 11 according to a second embodiment. In the second embodiment, slits ST_CELL, ST_WLC, and ST_LWI are formed using a plurality of holes H_ST_CELL, H_ST_WLC, and H_ST_LWI arranged in the X-direction. Thus, the slits ST_CELL, ST_WLC, and ST_LWI each extend in the arrangement direction of the plurality of holes (H_ST_CELL, H_ST_WLC, and H_ST_LWI). The slits ST_CELL and ST_WLC are formed by connecting the plurality of holes with an insulating film by filling the periphery of the plurality of holes (H_ST_CELL and H_ST_WLC) with an insulating film such as a silicon oxide film. The slit ST_LWI is formed by connecting the plurality of holes with a conductive material by filling the periphery of the plurality of holes (H_ST_LWI) with a conductive material such as tungsten.

For example, the slit ST_CELL includes a plurality of holes H_ST_CELL that penetrate the first stacked body 51_1 in the Z-direction and are arranged in the X-direction. The slit ST_CELL is formed by selectively removing a second insulating film 51c between first insulating films 51b adjacent to each other in the Z-direction through the plurality of holes H_ST_CELL, and filling an insulating film such as a silicon oxide film. Thereby, the slit ST_CELL is formed to connect the holes H_ST_CELL adjacent to each other in the X-direction with the insulating film. Thus, the slit ST_CELL extends in the X-direction in which the plurality of holes H_ST_CELL are arranged, and electrically separates the first stacked body 51_1 for each block BLK.

Furthermore, the slit ST_CELL also extends to the second stacked body 51_2 in the WLHU region Rwlhu from between the adjacent blocks BLK in the X-direction, and separates word line contacts WLC adjacent to each other in the Y-direction.

The slit ST_WLC includes a plurality of holes H_ST_WLC penetrating the plurality of first insulating films 51b between the first stacked body 51_1 and the second stacked body 51_2 in the Z-direction and arranged in the Y-direction. The slit ST_WLC fills an insulating film, such as a silicon oxide film, between the first insulating films 51b adjacent to each other in the Z-direction via the plurality of holes H_ST_WLC. Thereby, the slit ST_WLC is formed to connect the holes H_ST_WLC adjacent to each other in the Y-direction with the insulating film. Thus, the slit ST_WLC extends in the Y-direction in which the plurality of holes H_ST_WLC are arranged, and separates the cell region Rmc from the WLHU region Rwlhu.

The slit ST_WLC has the opening OP as in the first embodiment, and the cell region Rmc and the WLHU region Rwlhu communicate with each other at the opening OP.

The slit ST_LWI includes a plurality of holes H_ST_LWI that penetrate the third stacked body 51_3 in the Z-direction and are arranged in the X-direction. The slit ST_LWI is formed by selectively removing the second insulating film 51c between the first insulating films 51b adjacent to each other in the Z-direction through the plurality of holes H_ST_LWI and filling with a conductive material such as tungsten. Thereby, the slit ST_LWI is formed to connect the holes H_ST_LWI adjacent to each other in the X-direction with a conductive material. Thus, the slit ST_LWI extends in the X-direction in which the plurality of holes H_ST_LWI are arranged, and electrically connects an electrode film 51a of the first stacked body 51_1 and the word line contact WLC. The electrode film 51a of the slit ST_LWI functions as a path for connection to the word line contact WLC through the opening OP.

The spacer 26 is provided on the inner walls of the plurality of holes H_ST_LWI, and the holes H_ST_LWI themselves are electrically insulated from the third stacked body 51_3. Thus, electrode films 51a adjacent to each other in the Z-direction of the third stacked body 51_3 are electrically separated from each other.

Furthermore, in the second embodiment, a slit ST_WLC2 is provided. The slit ST_WLC2 extends in the Y-direction from the slit ST_CELL to the slit ST_LWI between the plurality of word line contacts WLC adjacent to each other in the X-direction. The slit ST_WLC2 includes a plurality of holes H_ST_WLC2 that penetrate the second stacked body 51_2 in the Z-direction and are arranged in the Y-direction. The slit ST_WLC2 is formed by selectively removing the second insulating film 51c between the first insulating films 51b via the plurality of holes H_ST_WLC2 and filling with an insulating film such as a silicon oxide film. Thereby, the slit ST_WLC2 is formed to connect the holes H_ST_WLC2 adjacent to each other in the Y-direction with the insulating film. Thus, the slit ST_WLC2 extends in the Y-direction in which the plurality of holes H_ST_WLC2 are arranged, and separates the word line contacts WLC adjacent to each other in the X-direction.

A plurality of holes H_REP are provided on both sides of the slit ST_CELL in the cell region Rmc and are arranged in the X-direction. The holes H_REP penetrate the slit ST_CELL or the first stacked body 51_1 in the Z-direction at a boundary portion between the slit ST_CELL and the first stacked body 51_1. The spacer 26 is provided on the inner wall of the hole H_REP, and a conductive material is provided inside the spacer 26. The hole H_REP is used when replacing the second insulating film 51c of the first stacked body 51_1 with the electrode film 51a.

A plurality of dummy columnar bodies DMC are provided on both sides of the third stacked body 51_3 in the WLHU region Rwlhu and are arranged in the X-direction. The dummy columnar body DMC penetrates the second stacked body 51_2 or the third stacked body 51_3 in the Z-direction at a boundary portion between the second stacked body 51_2 and the third stacked body 51_3. The dummy columnar body DMC has the same configuration as the columnar body CL, but does not function as the memory cell MC. The dummy columnar body DMC is used as a support for the first insulating film 51b of the third stacked body 51_3 when the second insulating film 51c of the third stacked body 51_3 is replaced with the electrode film 51a. The dummy columnar body DMC may not be necessarily provided.

The plurality of word line contacts WLC extend through the second stacked body 51_2 in the Z-direction, and are provided to the depth of each of the plurality of electrode films 51a (that is, the word lines WL). The word line contacts WLC are electrically connected to one of the electrode films 51a of the third stacked body 51_3 via a connect layer 27 provided at the bottom of each of the word line contacts. The third stacked body 51_3 has a plurality of electrode films 51a extending through the WLHU region Rwlhu in the X-direction, and is electrically connected to the plurality of electrode films 51a of the first stacked body 51_1 at the opening OP. Thus, the voltage of each word line WL can be controlled via each word line contact WLC.

The other configurations in the second embodiment may be the same as those in the first embodiment. Thus, in the second embodiment, it is possible to obtain the same effects as those in the first embodiment.

Next, a manufacturing method for the semiconductor memory device according to the second embodiment will be described.

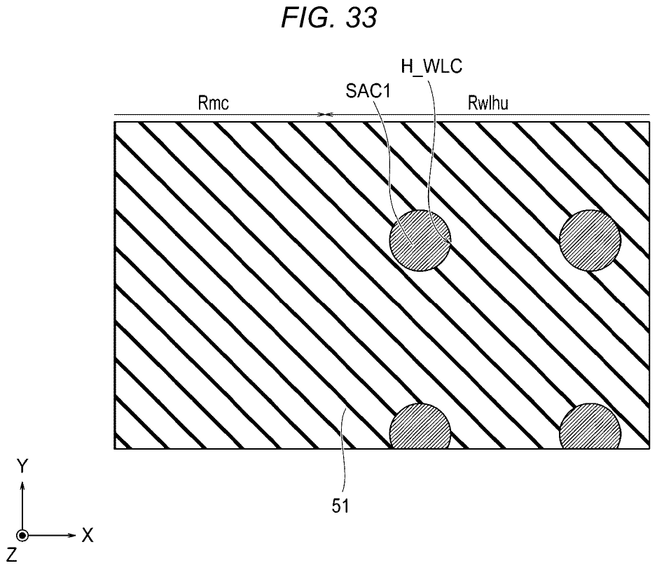

FIGS. 33 to 39 are plan views of a manufacturing method for the semiconductor memory device according to the second embodiment. As in the first embodiment, the stacked body 51 is formed by stacking the plurality of first insulating films 51b (for example, silicon oxide films) and the plurality of second insulating films 51c (for example, silicon nitride films).

Next, as shown in FIG. 33, contact holes H_WLC for the word line contacts WLC are formed in the stacked body 51. The plurality of contact holes H_WLC are formed to different depths in the WLHU region Rwlhu so as to reach respective one of the plurality of second insulating films 51c of the stacked body 51. Next, the contact holes H_WLC are filled with the sacrificial film SAC1 (for example, polysilicon or carbon).

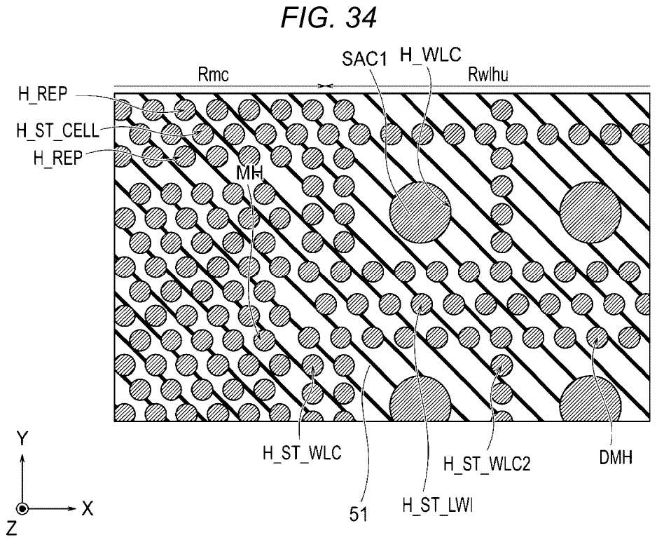

Next, as shown in FIG. 34, a plurality of memory holes MH are formed in the cell region Rmc. The memory holes MH are formed to penetrate the stacked body 51. At the same time, holes H_REP, H_ST_CELL, H_ST_WLC, H_ST_WLC2, and DMH are also formed to penetrate the stacked body 51. The memory holes MH and the holes H_REP, H_ST_CELL, H_ST_WLC, H_ST_WLC2, and DMH are also filled with the sacrificial film SAC1.

Next, the interlayer insulating film 58 is deposited on the surface of the stacked body 51, the silicon oxide film 58 on the holes H_ST_CELL, H_ST_WLC, and H_ST_WLC2 is removed using lithography and etching techniques, and the sacrificial film SAC1 is selectively removed using a wet etching method, an ashing method, or the like.

Next, a portion of each of the plurality of second insulating films 51c of the stacked body 51 is isotropically etched through the holes H_ST_CELL, H_ST_WLC, and H_ST_WLC2 by using a wet etching method. Thereby, the holes H_ST_CELL, H_ST_WLC, and H_ST_WLC2 communicate with each other in a space after the second insulating films 51c are removed.

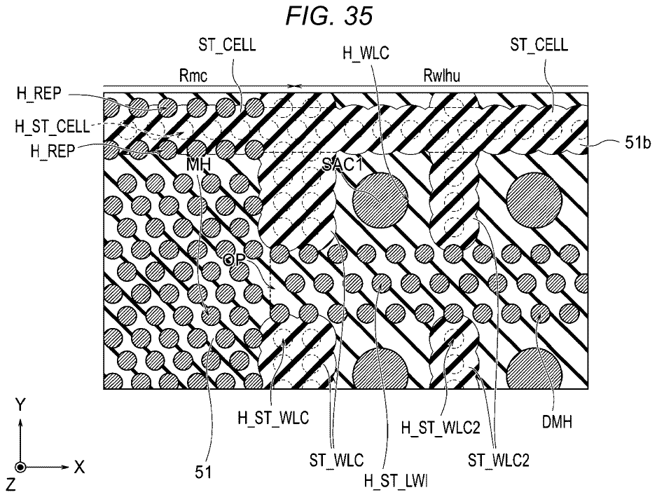

Next, a fourth insulating film is embedded in the space after the second insulating films 51c are removed through the holes H_ST_CELL, H_ST_WLC, and H_ST_WLC2. For the fourth insulating film, an insulating material such as a silicon oxide film is used. Thereby, as shown in FIG. 35, the slits ST_CELL, ST_WLC, and ST_WLC2 are configured with a stacked body of the first insulating film 51b and the fourth insulating film.

Next, the interlayer insulating film 58 is deposited on the surface of the stacked body 51, the interlayer insulating film 58 on the memory hole MH and the dummy hole DMH is removed using lithography and etching techniques, and the internal sacrificial film SAC1 is selectively removed using a wet etching method, an ashing method, or the like.

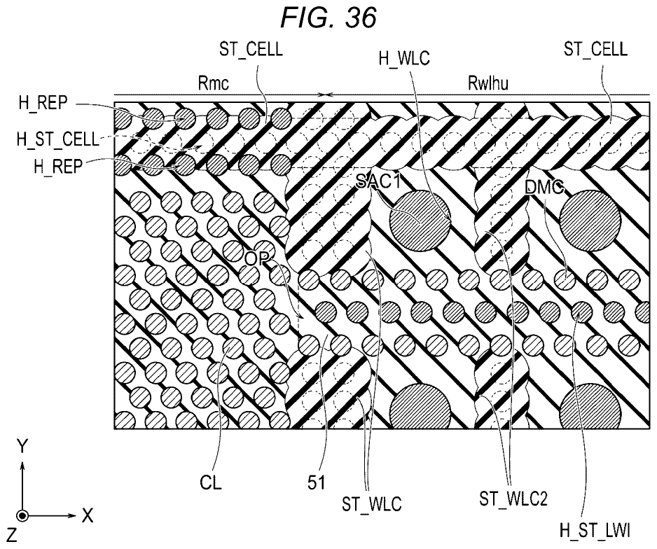

Next, as shown in FIG. 36, the columnar body CL is formed in the memory hole MH, and the dummy columnar body DMC is formed in the dummy hole DMH. The columnar body CL and the dummy columnar body DMC have the same configurations as those in the first embodiment, and are formed in the same process.

Next, the interlayer insulating film 58 is deposited on the surface of the stacked body 51, the interlayer insulating film 58 on the hole H_REP is removed using lithography and etching techniques, and the internal sacrificial film SAC1 is selectively removed using a wet etching method, an ashing method, or the like.

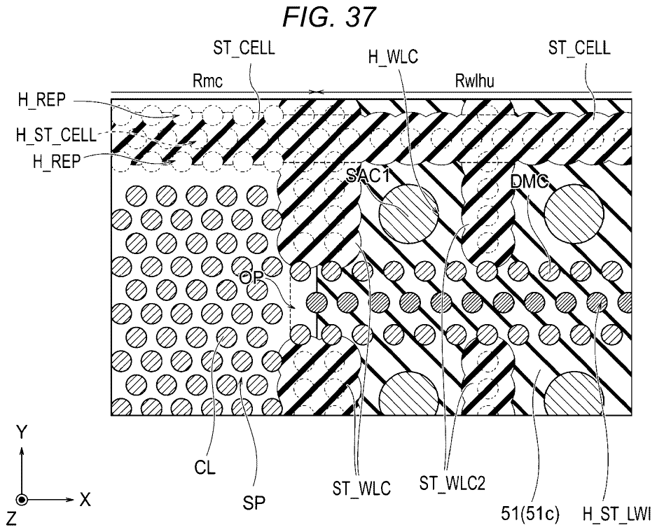

Next, the second insulating film 51c in the cell region Rmc is isotropically etched through the hole H_REP using a wet etching method. Thereby, as shown in FIG. 37, the second insulating film 51c around the columnar body CL in the cell region Rmc is removed, and the space SP is formed between the first insulating films 51b. The space SP extends to the vicinity of the opening OP. The second insulating film 51c in the WLHU region Rwlhu is left.

Next, the interlayer insulating film 58 is deposited on the surface of the stacked body 51, the interlayer insulating film 58 on the contact hole H_WLC is removed using lithography and etching techniques, and the internal sacrificial film SAC1 is selectively removed using a wet etching method, an ashing method, or the like.

Next, the spacer 26 (for example, a silicon oxide film) is formed on the inner wall of the contact hole H_WLC. Next, the spacer 26 at the bottom of the contact hole H_WLC is removed by anisotropic etching. Thereby, the spacer 26 at the bottom is removed while leaving the spacer 26 on the side wall of the contact hole H_WLC, and the second insulating film 51c is exposed at the bottom.

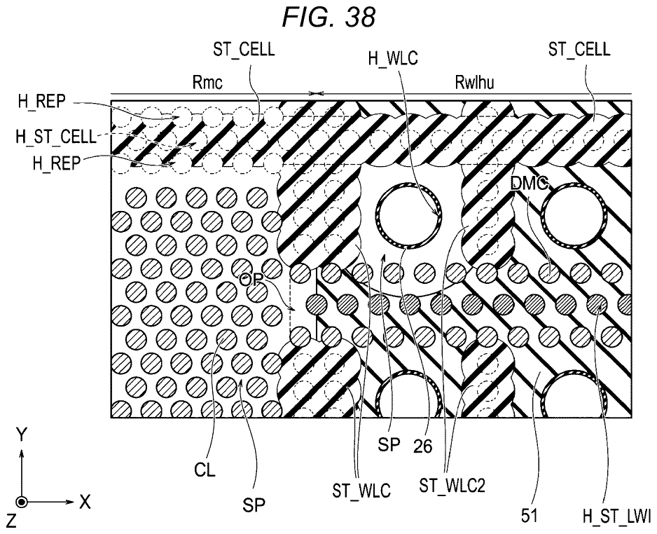

The second insulating film 51c of the stacked body 51 in the WLHU region Rwlhu is isotropically etched from the bottom of the contact hole H_WLC through the contact hole H_WLC using a wet etching method or a CDE method. Thereby, as shown in FIG. 38, the second insulating film 51c is etched in the X-Y plane from the bottom of the contact hole H_WLC toward the slits ST_CELL, ST_WLC, and ST_WLC2. The space SP is formed at a location where the second insulating film 51c is etched. The slits ST_CELL, ST_WLC, and ST_WLC2 function as etching stoppers.

Here, the plurality of contact holes H_WLC are formed to different depths in the WLHU region Rwlhu so as to reach respective one of the plurality of second insulating films 51c of the stacked body 51. Thus, the plurality of contact holes H_WLC form the space SP in a plurality of layers having different heights. The second insulating film 51c other than the bottom of the contact hole H_WLC is not etched because it is covered with the spacer 26. In FIG. 38, only one space SP formed at the bottom of one contact hole H_WL is shown.

Next, the interlayer insulating film 58 is deposited on the surface of the stacked body 51, the interlayer insulating film 58 on the plurality of holes H_ST_LWI is removed using lithography and etching techniques, and the internal sacrificial film SAC1 is selectively removed using a wet etching method, an ashing method, or the like.

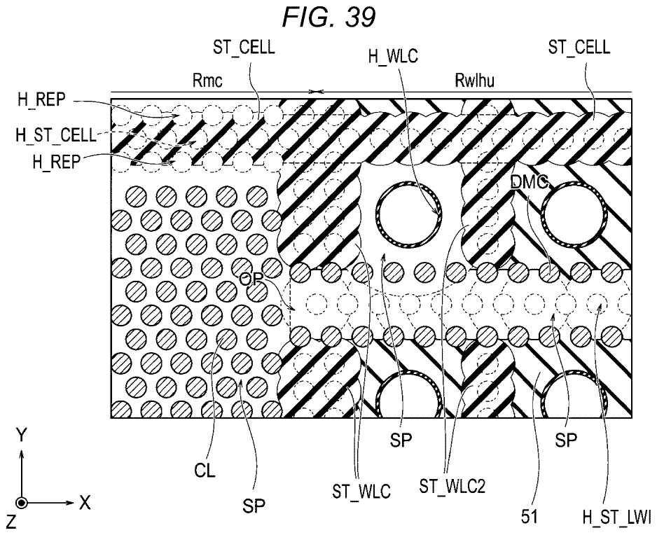

Next, the second insulating film 51c of the stacked body 51 in the WLHU region Rwlhu is isotropically etched through the plurality of holes H_ST_LWI by using a wet etching method or a CDE method. The plurality of holes H_ST_LWI communicate with each other in the X-direction in the space SP after the second insulating film 51c is removed. Thereby, as shown in FIG. 39, the space SP is continuously connected from the opening OP in the arrangement direction (i.e., X-direction) of the plurality of holes H_ST_LWI. In addition, the space SP from the holes H_ST_LWI communicates with the space SP from each contact hole H_WLC. The space SP from the hole H_ST_LWI is formed by etching the second insulating film 51c of each layer of the stacked body 51. At this time, the dummy columnar body DMC functions as a support pillar so that the first insulating film 51b between the contact hole H_WLC and the hole H_ST_LWI does not bend.

The space SP communicates with the hole H_ST_LWI of the WLHU region Rwlhu through the opening OP from the cell region Rmc. Furthermore, the space SP communicates with the corresponding contact hole H_WLC from the hole H_ST_LWI through the space SP of each layer.

Next, a thin block insulating film (for example, an aluminum oxide film) (not shown) is formed on the inner wall of the space SP formed between the first insulating films 51b through the hole H_REP, the hole H_ST_LWI, and the contact hole H_WLC. Furthermore, a titanium nitride film (not shown) is formed inside the block insulating film, and a conductive material is further embedded therein. For example, tungsten, molybdenum, and the like are used as the conductive material. Thereby, the electrode film 51a is formed between the first insulating films 51b adjacent to each other in the Z-direction. The first and third stacked bodies 51_1 and 51_3 are stacked bodies including a plurality of first insulating films 51b and a plurality of electrode films 51a. The second stacked body 51_2 is a stacked body including a plurality of first insulating films 51b and a plurality of second insulating films 51c. In this manner, in the first and third stacked bodies 51_1 and 51_3, the second insulating film 51c is replaced with the electrode film 51a.

Next, the material of the electrode film 51a formed on the inner walls of the hole H_REP, the hole H_ST_LWI, and the contact hole H_WLC is etched by a wet etching method to remove a short-circuit path between the electrode films 51a adjacent to each other in the Z-direction.

Next, the hole H_REP, the hole H_ST_LWI, and the contact hole H_WLC are filled with the sacrificial film SAC3 (for example, polysilicon or carbon). Next, the upper portion of the sacrificial film SAC3 is removed by an etch-back method using CMP or RIE, and then the interlayer insulating film 58 is deposited on the surface thereof. Thereafter, the interlayer insulating film 58 on the holes H_REP and H_ST_LWI is removed using a lithography technique, and the sacrificial film SAC3 in the holes H_REP and H_ST_LWI is selectively removed by a wet etching method, an ashing method, or the like. At this time, the sacrificial film SAC3 is left in the contact hole H_WLC. Next, the spacer 26 (for example, a silicon oxide film) is formed on the inner walls of the hole H_REP and the hole H_ST_LWI. Thereafter, a conductive material is further embedded inside the spacer 26. Thereby, the structure shown in FIG. 32 is obtained.

Thereafter, a multi-layer wiring layer (not shown) is formed, and the semiconductor memory device according to the second embodiment is completed through the processes described with reference to FIGS. 3 to 6.

According to the second embodiment, slits ST_CELL, ST_LWI, ST_WLC, and ST_WLC2 are formed in the arrangement direction of the holes H_ST_CELL, H_ST_LWI, H_ST_WLC, and H_ST_WLC2. Thereby, a region in the WLHU region Rwlhu where the second insulating film 51c is replaced with the electrode film 51a is limited, making it difficult for the first insulating film 51b to bend in the replacement process. Thus, it is not necessary to provide a support pillar in the WLHU region Rwlhu. That is, in the second embodiment, it is possible to obtain the same effects as in the first embodiment.

According to the second embodiment, the hole H_ST_CELL used to form the slit ST_CELL is provided separately from the hole H_REP used in the replacement process. Thus, the slit ST_CELL can be formed to extend not only to the cell region Rmc but also to the WLHU region Rwlhu. Thereby, the first insulating film 51b is even less likely to bend during the replacement process.

According to the second embodiment, in the WLHU region Rwlhu, the slit ST_WLC2 is provided between word line contacts WLC adjacent to each other in the X-direction. Thereby, the first insulating film 51b is even less likely to bend during the replacement process, and the second insulating film 51c that is etched through each contact hole H_WLC is limited, making it possible to curb a short circuit between the adjacent word line contacts WLC.

One block BLK has one opening OP and one slit ST_LWI. However, one block BLK may have a plurality of openings OP and a plurality of slits ST_LWI. In this case, the word line contacts WLC may be provided around each slit ST_LWI.

### Third Embodiment

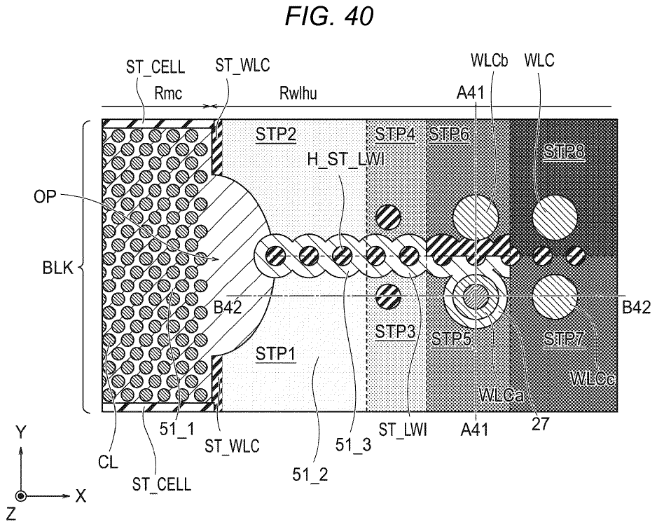

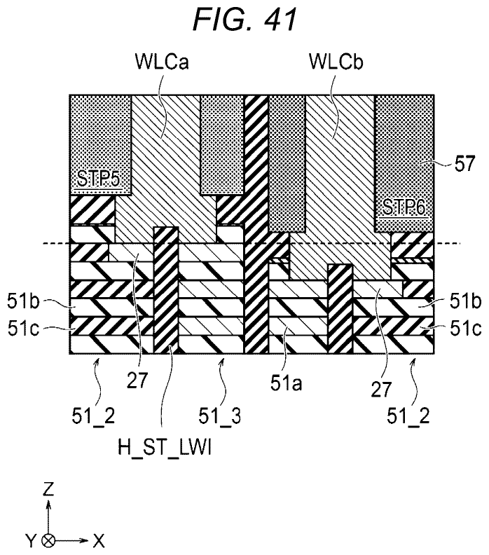

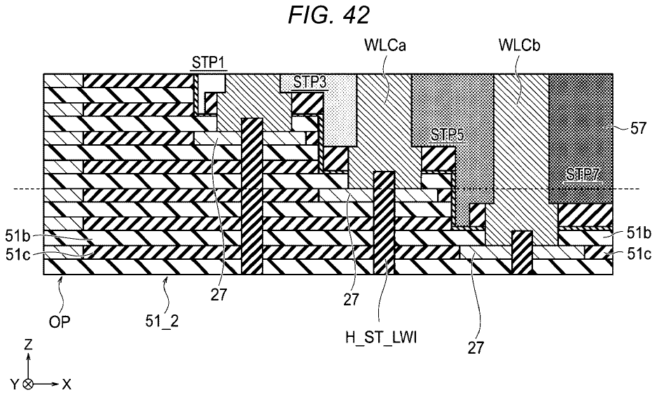

FIG. 40 is a plan view of a semiconductor memory device according to a third embodiment. FIG. 41 is a cross-sectional view taken along line A41-A41 in FIG. 40. FIG. 42 is a cross-sectional view taken along line B42-B42 in FIG. 40. FIG. 40 shows a plane at a height level indicated by dashed lines in FIGS. 41 and 42.

In the third embodiment, the second stacked body 51_2 is processed in a stepped shape in the WLHU region Rwlhu. For example, the second stacked body 51_2 has steps STP1 to STP8 as shown in FIG. 40. The steps STP1 to STP8 descend in order in the −Z-direction. Above the steps STP1 to STP8 of the second stacked body 51_2, the interlayer insulating film 57 is provided as shown in FIGS. 41 and 42. The plurality of word line contacts WLC penetrate the interlayer insulating film 57 provided on the second stacked body 51_2 in the Z-direction to the depths of corresponding electrode films 51a. The plurality of word line contacts WLC correspond to the steps STP1 to STP8, respectively, and are electrically connected to the plurality of electrode films 51a directly under the steps STP1 to STP8 via the connect layer 27. Thus, the plurality of word line contacts WLC extend to different depths in the interlayer insulating film 57.

The second stacked body 51_2 is processed in a stepped shape in both the X and Y-directions. Thus, the second stacked body 51_2 descends in a stepwise manner like the steps STP1, STP3, STP5, and STP7, and also descends in a stepwise manner like the steps STP2, STP4, STP6, and STP8 in the X-direction. Furthermore, the second stacked body 51_2 descends like the steps STP1 and STP2, descends like the steps STP3 and STP4, descends like the steps STP5 and STP6, and also descends like the steps STP7 and STP8 in the Y-direction.

The slit ST_LWI includes the plurality of holes H_ST_LWI that penetrate the third stacked body 51_3 in the Z-direction and are arranged in the X-direction. The slit ST_LWI is formed by filling a conductive material such as tungsten between first insulating films 51b adjacent to each other in the Z-direction through the plurality of holes H_ST_LWI. Thus, the slit ST_LWI is formed to connect the holes H_ST_LWI adjacent to each other in the X-direction with a conductive material. Thus, the slit ST_LWI extends in the X-direction in which the plurality of holes H_ST_LWI are arranged, and electrically connects an electrode film 51a of the first stacked body 51_1 and the word line contact WLC. The electrode film 51a of the slit ST_LWI functions as a path for connection to the word line contact WLC through the opening OP. That is, the slit ST_LWI (the electrode film 51a of the third stacked body 51_3) can function in the same manner as in the second embodiment. In addition, the third stacked body 51_3 can be formed in the same manner as in the second embodiment using the holes H_ST_LWI.

The plurality of word line contacts WLC are connected to the connect layers 27 provided at the bottoms thereof, and are electrically connected to the corresponding electrode films 51a of the third stacked body 51_3 through the connect layers 27. The configurations and formation methods of the word line contact WLC and the connect layer 27 may be the same as those in the second embodiment. However, the hole H_ST_LWI is provided to penetrate the third stacked body 51_3 below the interlayer insulating film 57, but is not provided in the interlayer insulating film 57. On the other hand, the word line contact WLC is provided to penetrate the interlayer insulating film 57 to the depth of the connect layer 27, but is not formed inside the second stacked body 51_2.

For example, as shown in FIGS. 41 and 42, a word line contact WLCa is formed to penetrate the interlayer insulating film 57 to the connect layer 27 corresponding to the step STP5. The connect layer 27 corresponding to the word line contact WLCa is connected to the electrode film 51a (that is, the word line WL) provided at the same height as the connect layer 27. Thereby, the word line contact WLCa can control the voltage of the corresponding word line WL.

A word line contact WLCb in FIG. 41 is formed to penetrate the interlayer insulating film 57 to the connect layer 27 corresponding to the step STP6 which is one step below the word line contact WLCa. The connect layer 27 corresponding to the word line contact WLCb is connected to the electrode film 51a provided at the same height as the connect layer 27. Thereby, the word line contact WLCb can control the voltage of the corresponding word line WL.

A word line contact WLCc in FIG. 42 is formed to penetrate the interlayer insulating film 57 to the connect layer 27 corresponding to the step STP7 which is one step below the word line contact WLCb. The connect layer 27 corresponding to the word line contact WLCc is connected to the electrode film 51a provided at the same height as the connect layer 27. Thereby, the word line contact WLCc can control the voltage of the corresponding word line WL.

Similarly, for the other steps STP1 to STP4 and STP8, the word line contacts WLC are electrically connected to the corresponding word lines WL. Thereby, the plurality of word line contacts WLC can control the voltages of the corresponding word lines WL.

The third embodiment differs from the second embodiment in that the second stacked body 51_2 is processed in a stepped shape in the WLHU region Rwlhu, and the interlayer insulating film 57 is provided thereon. However, the configurations in the third embodiment substantially correspond to the configurations in the second embodiment. Thus, in the third embodiment, a support pillar is not necessary in the WLHU region Rwlhu, and the same effects as in the second embodiment can be obtained. In addition, a manufacturing method according to the third embodiment can be understood by referring to the manufacturing method according to the second embodiment. Thus, the description of the manufacturing method according to the third embodiment is omitted here.

One block BLK has one opening OP and one slit ST_LWI. However, one block BLK may have a plurality of openings OP and a plurality of slits ST_LWI. In this case, word line contacts WLC may be provided around each slit ST_LWI.

### Fourth Embodiment

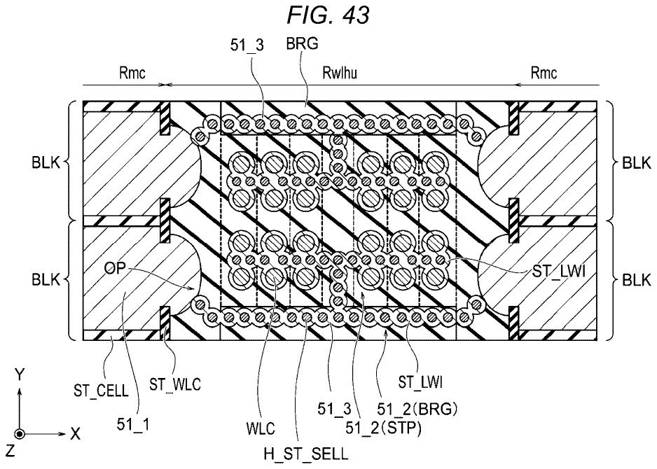

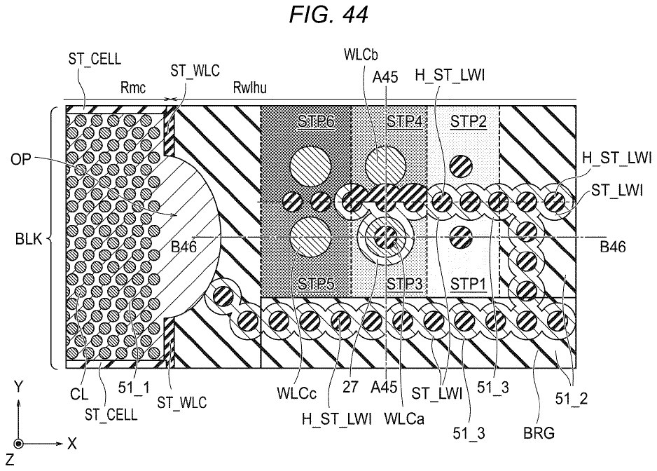

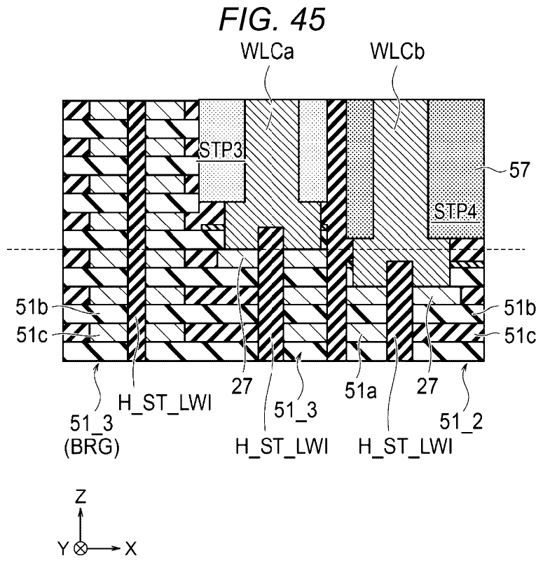

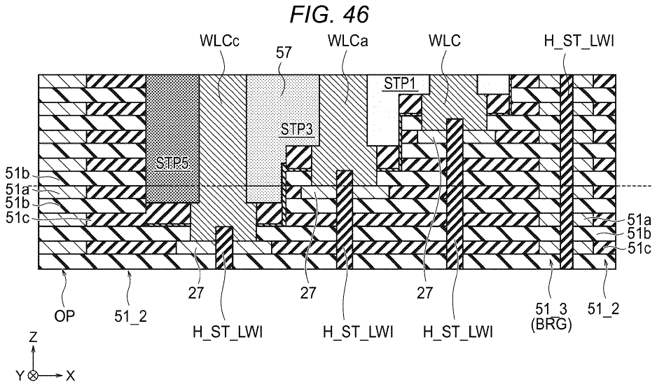

FIGS. 43 and 44 are plan views of a semiconductor memory device according to a fourth embodiment. FIG. 44 shows an enlarged plane of a portion of the structure shown in FIG. 43. FIG. 45 is a cross-sectional view taken along line A45-A45 in FIG. 44. FIG. 46 is a cross-sectional view taken along line B46-B46 in FIG. 44. FIG. 44 shows a plane at a height level indicated by dashed lines in FIGS. 45 and 46.

As shown in FIG. 43, in the fourth embodiment, a WLHU region Rwlhu is provided between a plurality of cell regions Rmc adjacent to each other in the X-direction, and is shared by memory cell arrays 11.

In the fourth embodiment, the WLHU region Rwlhu includes a step portion STP and a bridge portion BRG. The step portion STP is the second stacked body 51_2 that is processed in a stepped shape so as to descend from a central portion of the WLHU region Rwlhu toward the cell regions Rmc on both sides. The bridge portion BRG is the second stacked body 51_2 that is not processed in a stepped shape and is left to the uppermost layer and connects the plurality of adjacent cell regions Rmc.

In the fourth embodiment, the word line contact WLC is connected to the slit ST_LWI provided in the bridge portion BRG via the slit ST_LWI provided in the step portion STP. The slit ST_LWI is also provided in the bridge portion BRG, and branches out in the ±X-direction in the bridge portion BRG to be connected to a plurality of adjacent memory cell arrays 11. The slit ST_LWI includes the hole H_ST_LWI and the third stacked body 51_3 provided around the hole H_ST_LWI. The word line contact WLC is electrically connected to the electrode film 51a (i.e., word line WL) of the cell region Rmc via the electrode film 51a of the third stacked body 51_3.

For example, as shown in FIG. 44, the second stacked body 51_2 has steps STP1 to STP6. The steps STP1 to STP6 descend in order in the −Z-direction. As shown in FIGS. 45 and 46, the interlayer insulating film 57 is provided above the steps STP1 to STP6 of the second stacked body 51_2. The plurality of word line contacts WLC penetrate the interlayer insulating film 57 provided on the second stacked body 51_2 in the Z-direction to the depths of the corresponding electrode films 51a. The plurality of word line contacts WLC correspond to the steps STP1 to STP6, respectively, and are electrically connected to the plurality of electrode films 51a directly under the steps STP1 to STP6 via the connect layer 27. Thus, the plurality of word line contacts WLC extend to different depths in the interlayer insulating film 57.

The second stacked body 51_2 is processed in a stepped shape in both the X and Y-directions. Thus, the second stacked body 51_2 descends in a stepwise manner like the steps STP1, STP3, and STP5 in the X-direction, and also descends in a stepwise manner like steps STP2, STP4, and STP6. Furthermore, the second stacked body 51_2 descends like the steps STP1 and STP2, descends like the steps STP3 and STP4, and descends like the steps STP5 and STP6 in the Y-direction.

The slit ST_LWI has the same configuration as that in the third embodiment. The slit ST_LWI extends in the X-direction in which the plurality of holes H_ST_LWI are arranged, and electrically connects the electrode film 51a of the first stacked body 51_1 and the word line contact WLC. The electrode film 51a of the slit ST_LWI functions as a path for connection to the word line contact WLC through the opening OP.

In the fourth embodiment, the slit ST_LWI is provided across the step portion STP, the second stacked body 51_2 in the central portion of the WLHU region Rwlhu, and the second stacked body 51_2 of the bridge portion BRG. Furthermore, the slit ST_LWI branches out toward the plurality of cell regions Rmc adjacent to each other in the X-direction in the bridge portion BRG, and is connected to both the first stacked bodies 51_1 at the openings OP in the plurality of cell regions Rmc. Thereby, the word line contact WLC is electrically connected in common to the corresponding word lines WL in the plurality of adjacent cell regions Rmc.

The plurality of word line contacts WLC are connected to the connect layers 27 provided at the bottoms thereof, and are electrically connected to the corresponding electrode films 51a of the third stacked body 51_3 through the connect layers 27. The configurations and formation methods of the word line contact WLC and the connect layer 27 may be the same as those in the second embodiment. However, the hole H_ST_LWI is provided to penetrate the third stacked body 51_3 below the interlayer insulating film 57, but is not provided in the interlayer insulating film 57. On the other hand, the word line contact WLC is provided to penetrate the interlayer insulating film 57 to the depth of the connect layer 27, but is not formed inside the second stacked body 51_2.

For example, as shown in FIGS. 45 and 46, the word line contact WLCa is formed to penetrate the interlayer insulating film 57 to the connect layer 27 corresponding to the step STP3. The connect layer 27 corresponding to the word line contact WLCa is connected to the electrode film 51a (that is, the word line WL) provided at the same height as the connect layer 27. Thereby, the word line contact WLCa can control the voltage of the corresponding word line WL.

The word line contact WLCb in FIG. 45 is formed to penetrate the interlayer insulating film 57 to the connect layer 27 corresponding to the step STP4 which is one step below the word line contact WLCa. The connect layer 27 corresponding to the word line contact WLCb is connected to the electrode film 51a provided at the same height as the connect layer 27. Thereby, the word line contact WLCb can control the voltage of the corresponding word line WL.

The word line contact WLCc in FIG. 46 is formed to penetrate the interlayer insulating film 57 to the connect layer 27 corresponding to the step STP5 which is one step below the word line contact WLCb. The connect layer 27 corresponding to the word line contact WLCc is connected to the electrode film 51a provided at the same height as the connect layer 27. Thereby, the word line contact WLCc can control the voltage of the corresponding word line WL.

Similarly, for the other steps STP1, STP2, and STP6, the word line contacts WLC are electrically connected to the corresponding word lines WL. That is, the plurality of connect layers 27 electrically connect the plurality of word line contacts WLC to the plurality of electrode films 51a in the adjacent memory cell arrays 11. Thereby, the plurality of word line contacts WLC can separately control the voltages of the corresponding word lines WL.

The fourth embodiment differs from the third embodiment in the arrangement of the WLHU region Rwlhu, the configuration of the step portion STP, and the configuration of the bridge portion BRG. Thus, the fourth embodiment differs from the third embodiment in the path of the slit ST_LWI that electrically connects the word line contact WLC and the word line WL. However, the other configurations in the fourth embodiment correspond to the configurations in the third embodiment. Thus, also in the fourth embodiment, a support pillar is not necessary in the WLHU region Rwlhu, and the same effects as in the second embodiment can be obtained. Similarly to the third embodiment, a manufacturing method according to the fourth embodiment can be understood by referring to the manufacturing method according to the second embodiment. Thus, the description of the manufacturing method according to the fourth embodiment is omitted here.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a plurality of first electrode films arranged in a first direction;
a plurality of first insulating films arranged in the first direction;
a plurality of second insulating films arranged in the first direction;
a first stacked region in which the first electrode films and the first insulating films are alternately stacked in the first direction;
a second stacked region adjacent to the first stacked region in a second direction that is perpendicular to the first direction and in which the first insulating films and the second insulating films are alternately stacked in the first direction;
a third stacked region extending from the first stacked region in the second direction and in which the first electrode films and the first insulating films are alternately stacked in the first direction;
a first columnar body including a semiconductor layer that penetrates the first electrode films and the first insulating films in the first stacked region and forms a plurality of memory cells at intersections with the first electrode films;
a plurality of contacts extending in the first direction in the second stacked region, each of the contacts reaching, in the first direction, a level of a corresponding one of the first electrode films; and
a plurality of connection layers electrically connecting the contacts and the corresponding first electrode films.

2. The semiconductor memory device according to claim 1, further comprising:
a plurality of first slits that penetrate the first electrode films and the first insulating films in the first stacked region, extend in the second direction, and divide the first stacked region into a plurality of memory blocks.

3. The semiconductor memory device according to claim 2, further comprising:
a second slit that penetrates the first electrode films and the first insulating films in the first stacked region or the first insulating films and the second insulating films in the second stacked region along an interface between the first and second stacked regions, and extends in a third direction perpendicular to the first and second directions.

4. The semiconductor memory device according to claim 3, wherein
the second slit has an opening through which one of the memory blocks is connected to the third stacked region.

5. The semiconductor memory device according to claim 3, further comprising:
a third slit that penetrates the first electrode films and the first insulating films in the third stacked region and extends in the second direction.

6. The semiconductor memory device according to claim 1, wherein
each of the second insulating films in the second stacked region is located, in the first direction, at a same level of a corresponding one of the first electrode films in the first and third stacked regions.

7. The semiconductor memory device according to claim 1, further comprising:
a plurality of first holes that penetrate the first electrode films and the first insulating films in the first stacked region and are arranged in the second direction.

8. The semiconductor memory device according to claim 7, further comprising:
a plurality of second holes that extend parallel to the first holes along an interface between the first and second stacked regions and are arranged in a third direction perpendicular to the first and second directions.

9. The semiconductor memory device according to claim 8, further comprising:
a plurality of third holes that penetrate the first electrode films and the first insulating films in the third stacked region and are arranged in the second direction.

10. The semiconductor memory device according to claim 1, wherein
one of the contacts farther from the first stacked region reaches a lower level than another one of the contacts that is closer to the first stacked region.

11. The semiconductor memory device according to claim 10, wherein
two of the contacts that are arranged in a third direction perpendicular to the first and second directions reach different levels.

12. The semiconductor memory device according to claim 1, further comprising:
a fourth stacked region extending from the first stacked region in the second direction and parallel to the third stacked region and in which the first electrode films and the first insulating films are alternately stacked in the first direction, wherein
the contacts are between the third and fourth stacked regions.

13. The semiconductor memory device according to claim 1, wherein
two or more of the contacts are arranged in a third direction perpendicular to the first and second directions between the third and fourth stacked regions.

14. The semiconductor memory device according to claim 1, further comprising:
a third insulating film on or above an uppermost one of the second insulating films, wherein
the contacts penetrate the third insulating film.

15. The semiconductor memory device according to claim 1, further comprising:
an array chip including the first through third stacked regions; and
a circuit chip adhered to the array chip in the first direction.

16. The semiconductor memory device according to claim 15, wherein
the array chip includes a wiring connected to the first columnar body and extending in the first direction, and
the circuit chip includes a transistor electrically connected to the wiring of the array chip.

17. The semiconductor memory device according to claim 15, wherein
the array chip includes:
a metal pad to which a substrate or another device can be connected, and
a via plug extending parallel to the first columnar body and electrically connected to the metal pad.

18. A method for manufacturing a semiconductor memory device, the method comprising:
alternately stacking first insulating films and second insulating films in a first direction to form a stacked body;
forming a first slit hole between a first region of the stacked body and a second region of the stacked body that is adjacent to the first region in a second direction perpendicular to the first direction such that the first slit hole has an opening;
forming a plurality of contact holes in the second region such that each of the contact holes reaches one of the second insulating films;
forming a plurality of second slit holes that penetrate the first region and extend in the second direction;
forming a plurality of third slit holes that penetrate the second region and extend in the second direction;
removing a portion of the second insulating film at a bottom of each of the contact holes via said each of the contact holes and removing a portion of the second insulating films in the second region through the third slit holes such that the contact holes and the third slit holes communicate with each other;
removing the second insulating films in the first region via the second slit holes such that the second slit holes communicate with the third slit holes through the opening; and
embedding, via the contact holes, the second slit holes, and the third slit holes, a conductive material in a space which is formed between the first insulating films by removing the second insulating film, to form an electrode film.

19. The method according to claim 18, wherein
each of the contact holes reaches a corresponding one of the second insulating films at a different level in the first direction.

20. The method according to claim 18, further comprising:
bonding an array wafer including the stacked body in which the electrode film is formed, to a circuit wafer including a circuit chip such that the electrode film is electrically connected to the circuit chip.
